(19) United States
(12) Patent Application Publication
(10) Pub. No.: US 2023/0255044 A1
(43) Pub. Date: Aug. 10, 2023

(54) ORGANIC LIGHT-EMITTING ELEMENT AND DISPLAY APPARATUS, IMAGING APPARATUS, ELECTRONIC DEVICE, ILLUMINATION APPARATUS, MOVING OBJECT, AND EXPOSURE LIGHT SOURCE INCLUDING THE SAME

(71) Applicant: CANON KABUSHIKI KAISHA, Tokyo (JP)

(72) Inventors: ITARU TAKAYA, Kanagawa (JP); NAOKI YAMADA, Tokyo (JP); YOSUKE NISHIDE, Kanagawa (JP); HIROKAZU MIYASHITA, Kanagawa (JP)

(21) Appl. No.: 18/163,177

(22) Filed: Feb. 1, 2023

(30) Foreign Application Priority Data
Feb. 7, 2022 (JP) 2022-016846

(51) Int. Cl. H10K 50/12; H10K 50/13; H10K 50/165; H10K 59/90; H10K 85/60

(52) U.S. Cl. CPC H10K 50/12; H10K 50/13; H10K 50/165; H10K 59/90; H10K 85/657; H10K 2101/30

(57) ABSTRACT

The present disclosure provides an organic element including an anode, a first layer, a functional layer in contact with the first layer, and a cathode in this order. Energy levels of a first host material and a first dopant material that form the first layer and an organic material that forms the functional layer satisfy specific relations.

### BACKGROUND OF THE INVENTION

### Field of the Invention

The aspect of the embodiments relates to an organic light-emitting element which is one of light-emitting elements and to devices and apparatuses which include the element.

### Description of the Related Art

In recent years, research and development has been intensively conducted on full-color light-emitting arrays including organic light-emitting elements (hereinafter may be referred to as “organic electroluminescence elements” or “organic EL elements”). In a typical organic light-emitting element, a hole transport layer, a light-emitting layer, an electron transport layer, and a cathode are sequentially formed on an anode. Furthermore, a hole blocking layer may be provided on the light-emitting-layer side of the electron transport layer, and an electron injection layer may be provided on the cathode side of the electron transport layer. In the case of producing such a full-color light-emitting array, different light-emitting layers may be individually arranged for pixels (elements), or white organic light-emitting elements including a white-light-emitting layer and individually provided with any of red, green, and blue color filters for pixels may be used. With regard to the white organic light-emitting elements, light-emitting materials that emit light of three colors, namely, red, green, and blue, corresponding to the color filters are often used.

Japanese Patent Laid-Open No. 2014-22205 (hereinafter referred to as PTL 1) discloses a white organic light-emitting element in which a dual-color light-emitting layer containing a red light-emitting material and a green light-emitting material in a single light-emitting layer and a blue-light-emitting layer having electron-trapping properties are adjacently stacked, and the two light-emitting layers contain the same host material to reduce the drive voltage of the white EL element.

While the white organic light-emitting element disclosed in PTL 1 has good light emission balance, there may be a problem of an increase in the drive voltage of the element because the white organic light-emitting element includes a hole blocking layer in contact with the blue-light-emitting layer having electron-trapping properties. Furthermore, hole accumulation tends to occur at the interface between the blue-light-emitting layer having electron-trapping properties and the hole blocking layer when energized, resulting in a problem in that a decrease in the durability of the element is likely to proceed.

### SUMMARY OF THE INVENTION

An organic light-emitting element comprising, in sequence: an anode; a first light-emitting layer; a functional layer in contact with the first light-emitting layer; and a cathode. The first light-emitting layer contains a first host material and a first dopant material, and when the first host material has a LUMO energy level LUMOₕ₁, the first dopant material has a LUMO energy level LUMO_{d1}, the first host material has a HOMO energy level HOMOₕ₁, the first dopant material has a HOMO energy level HOMO_{d1}, and an organic material that forms the functional layer has a HOMO energy level HOMO_{FL}, formulae [1] to [3] are satisfied:

LUMOₕ₁>LUMO_{d1} [1]

HOMOₕ₁>HOMO_{d1} [2]

HOMO_{FL}>HOMOₕ₁ [3].

Further features of the disclosure will become apparent from the following description of exemplary embodiments with reference to the attached drawings.

### BRIEF DESCRIPTION OF THE DRAWINGS

FIG. 1A is a schematic sectional view of an organic light-emitting element according to an embodiment of the disclosure in a thickness direction. FIG. 1B is a schematic energy diagram illustrating the energy levels of a first light-emitting layer and adjacent layers.

FIG. 2A is a schematic sectional view of an organic light-emitting element according to another embodiment of the disclosure in a thickness direction. FIG. 2B is a schematic energy diagram illustrating the energy levels of a first light-emitting layer, a second light-emitting layer, and adjacent layers.

FIG. 3A is a schematic diagram of an image forming apparatus according to an embodiment of the disclosure. FIGS. 3B and 3C are schematic views each illustrating a form in which a plurality of light-emitting portions of an exposure light source are arranged on a long substrate.

FIG. 4A is a schematic sectional view illustrating an example of a pixel of a display apparatus according to an embodiment of the disclosure. FIG. 4B is a schematic sectional view illustrating an example of a display apparatus including organic light-emitting elements according to an embodiment of the disclosure.

FIG. 5 is a schematic view illustrating an example of a display apparatus according to an embodiment of the disclosure.

FIG. 6A is a schematic view illustrating an example of a display apparatus according to an embodiment of the disclosure. FIG. 6B is a schematic view illustrating an example of a foldable display apparatus.

FIG. 7A is a schematic view illustrating an example of an imaging apparatus according to an embodiment of the disclosure. FIG. 7B is a schematic view illustrating an example of an electronic device according to an embodiment of the disclosure.

FIG. 8 is a schematic view illustrating an example of an illumination apparatus according to an embodiment of the disclosure.

FIG. 9 is a schematic view illustrating an example of an automobile including a vehicle lighting fixture according to an embodiment of the disclosure.

FIG. 10A is a schematic view illustrating an example of a wearable device according to an embodiment of the disclosure. FIG. 10B is a schematic view illustrating an example of a wearable device according to an embodiment of the disclosure, the wearable device including an imaging apparatus.

### DESCRIPTION OF THE EMBODIMENTS

An organic light-emitting element according to the disclosure is configured so that, in organic light-emitting layers disposed between an anode and a cathode, the energy levels of a light-emitting layer, a functional layer, and furthermore, an electron transport layer satisfy specific relations. Thus, the organic light-emitting element has a low drive voltage and durability that is less likely to decrease. Hereinafter, a configuration <1> and configurations <2> to <6> of the disclosure will be described.

### Configuration <1>

In an organic light-emitting element including, in sequence, an anode, a first light-emitting layer, a functional layer in contact with the first light-emitting layer, and a cathode, the first light-emitting layer contains a first host material (hereinafter referred to as a “first host”) and a first dopant material (hereinafter referred to as a “first dopant”). When the first host has a LUMO energy level LUMOₕ₁, the first dopant has a LUMO energy level LUMO_{d1}, the first host has a HOMO energy level HOMOₕ₁, the first dopant has a HOMO energy level HOMO_{d1}, and an organic material that forms the functional layer has a HOMO energy level HOMO_{FL}, formulae [1] to [3] below are satisfied.

Note that HOMO is the highest occupied molecular orbital, LUMO is the lowest unoccupied molecular orbital, the energy level of HOMO is also referred to as a “HOMO level”, and the energy level of LUMO is also referred to as a “LUMO level”. The HOMO level and the LUMO level are determined with respect to the vacuum level and are negative values in the case of typical molecules. Herein, when HOMO levels and LUMO levels are compared by using a sign of inequality, relations of magnitudes that are not absolute values are used. In Examples described later, methods for measuring values of a HOMO level and a LUMO level used in the disclosure and measurement results of some materials will be described.

LUMOₕ₁>LUMO_{d1} [1]

HOMOₕ₁>HOMO_{d1} [2]

HOMO_{FL}>HOMOₕ₁ [3]

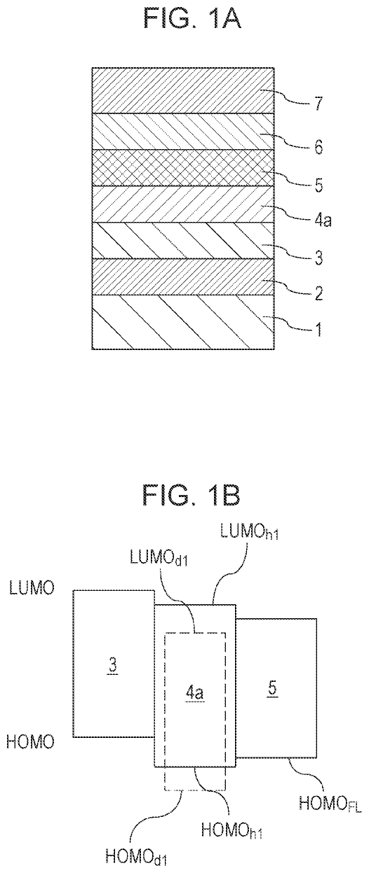

A description will be made with reference to FIGS. 1A and 1B. FIG. 1A is a schematic sectional view of an organic light-emitting element according to an embodiment of the disclosure in a thickness (stacking) direction. Referring to the figures, the organic light-emitting element includes a substrate 1, an anode 2, a hole transport layer 3, a first light-emitting layer 4a, a functional layer 5, an electron transport layer 6, and a cathode 7. In the disclosure, the first light-emitting layer 4a is a layer having a light-emitting function among organic compound layers disposed between the anode 2 and the cathode 7.

The first host contained in the first light-emitting layer 4a refers to a material serving as a main component among materials contained in the first light-emitting layer 4a. More specifically, the first host refers to a material having a content of more than 50% by mass in the first light-emitting layer 4a among materials contained in the first light-emitting layer 4a.

On the other hand, the first dopant is a material that does not serve as the main component among the materials contained in the first light-emitting layer 4a. More specifically, the first dopant refers to a material having a content of less than 50% by mass in the first light-emitting layer 4a among the materials contained in the first light-emitting layer 4a.

FIG. 1B is a schematic energy diagram illustrating the energy levels of the first light-emitting layer 4a and adjacent layers that form the organic light-emitting element in FIG. 1A. When electrons are injected from the functional layer 5 into the first light-emitting layer 4a that satisfies formula [1], the electrons enter LUMO_{d1} having a low energy level and do not conduct because the dopant has a low concentration, and thus the electrons are trapped in LUMO_{d1}.

When holes are injected from the hole transport layer 3 into the first light-emitting layer 4a that satisfies formula [2], the holes enter HOMOₕ₁ having a high energy level and conduct through HOMOₕ₁ toward the functional layer 5, and in the middle of the conduction, the holes recombine with electrons to emit light. That is, the first light-emitting layer 4a that satisfies formulae [1] and [2] has electron trapping properties and hole transporting properties.

In the disclosure, the functional layer 5 is disposed on the cathode 7 side of the first light-emitting layer 4a while being in contact with the first light-emitting layer 4a. The functional layer 5 and the first host of the first light-emitting layer 4a satisfy formula [3], and holes that conduct through HOMOₕ₁ but that have failed to recombine with electrons enter HOMO_{FL} without being blocked at the HOMO level of the functional layer 5.

Accordingly, in the organic light-emitting element according to the disclosure, accumulation of holes does not occur in the first light-emitting layer 4a, the drive voltage of the element is low, and a decrease in durability of the element due to hole accumulation is unlikely to proceed.

In configuration <1>, formula [4] below may be satisfied in formulae [1] and [2], and/or formula [3-1], and furthermore, formula [3-2] may be satisfied in formula [3].

|LUMOₕ₁−LUMO_{d1}|>|HOMOₕ₁−HOMO_{d1}| [4]

HOMO_{FL}−HOMOₕ₁≥0.05 [eV] [3-1]

HOMO_{FL}−HOMOₕ₁≥0.15 [eV] [3-2]

### Configuration <2>

A second light-emitting layer is disposed on the anode side of the first light-emitting layer while being in contact with the first light-emitting layer, and the second light-emitting layer contains a second host material (hereinafter referred to as a “second host”) and a second dopant material (hereinafter referred to as a “second dopant”). Furthermore, when the second dopant of the second light-emitting layer has a HOMO level HOMO_{d2} and the second host of the second light-emitting layer has a HOMO level HOMOₕ₂, formula [5] below is satisfied.

HOMO_{d2}>HOMOₕ₂ [5]

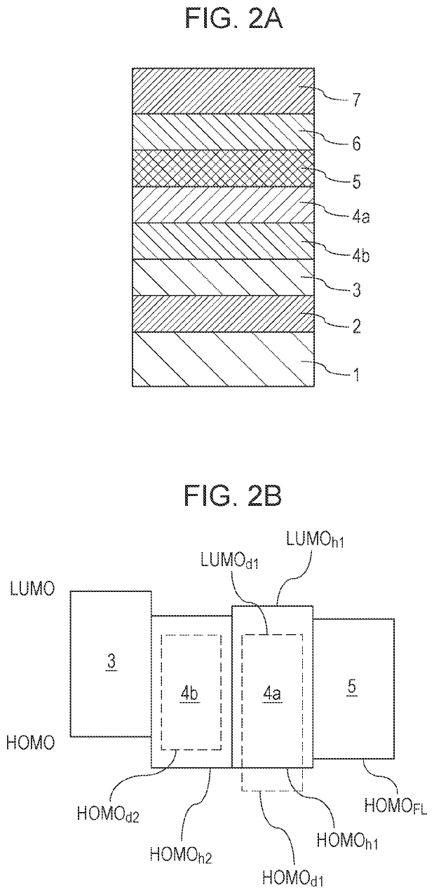

A description will be made with reference to FIGS. 2A and 2B. FIG. 2A is a schematic sectional view of an organic light-emitting element according to another embodiment of the disclosure in a thickness direction. In this embodiment, a second light-emitting layer 4b is disposed on the anode 2 side of the first light-emitting layer 4a while being in contact with the first light-emitting layer 4a. The second light-emitting layer 4b also has a light-emitting function as in the first light-emitting layer 4a and contains a second host serving as a main component and a second dopant.

FIG. 2B is a schematic energy diagram illustrating the energy levels of the first light-emitting layer 4a, the second light-emitting layer 4b, and adjacent layers that form the organic light-emitting element of this embodiment. As in the description in FIGS. 1A and 1B, when electrons are injected from the functional layer 5 into the first light-emitting layer 4a that satisfies formula [1], the electrons enter LUMO_{d1} having a low energy level and do not conduct because the first dopant has a low concentration, and thus the electron are trapped in LUMO_{d1}.

Here, when the first dopant has a sufficiently low concentration, electrons that cannot enter LUMO_{d1} enter LUMOₕ₁ having high energy and conduct through LUMOₕ₁ toward the second light-emitting layer 4b. Accordingly, in this embodiment, since the first dopant has a sufficiently low concentration, some of the electrons are trapped in LUMO_{d1}, and some of the electrons pass through the first light-emitting layer 4a, are injected into the second light-emitting layer 4b, and recombine with holes trapped in HOMO_{d2} in the second light-emitting layer 4b to emit light in the second light-emitting layer 4b.

When holes are injected from the hole transport layer 3 into the second light-emitting layer 4b that satisfies formula [5], the holes enter HOMO_{d2} having a high energy level and do not conduct because the second dopant has a low concentration, and thus the holes are trapped in HOMO_{d2}. Here, when the second dopant has a sufficiently low concentration, holes that cannot enter HOMO_{d2} enter HOMOₕ₂ having a low energy level and conduct toward the first light-emitting layer 4a.

Accordingly, since the second dopant has a sufficiently low concentration, some of the holes are trapped in HOMO_{d2}, and some of the holes pass through the second light-emitting layer 4b and are injected into the first light-emitting layer 4a. Since the first light-emitting layer 4a satisfies formula [2], the holes conduct through HOMOₕ₁ and recombine with electrons trapped in LUMO_{d1} to emit light in the first light-emitting layer 4a.

Here, in one embodiment, the concentration of the second dopant is to be sufficiently low and is 0.1% by mass to 5% by mass.

In the disclosure, the functional layer 5 is in contact with the cathode side of the first light-emitting layer 4a. The functional layer 5 and the first host of the first light-emitting layer 4a satisfy formula [3], and, also in this case, holes that conduct through HOMOₕ₁ but that have failed to recombine with electrons enter HOMO_{FL} without being blocked at the HOMO level of the functional layer 5.

Accordingly, in the organic light-emitting element according to this embodiment, accumulation of holes does not occur in the first light-emitting layer 4a, the drive voltage of the element is low, and a decrease in durability of the element is unlikely to proceed.

In configuration <2>, formula [5-1] below may be satisfied in formula [5].

HOMO_{d2}−HOMOₕ₂>0.4 [eV] [5-1]

As described above, the second light-emitting layer 4b according to this embodiment traps some of holes, and the trapped holes recombine with electrons that have passed through the first light-emitting layer 4a to emit light in the second light-emitting layer 4b. Here, unless the trap depth is sufficient, the probability of successfully trapping holes decreases. The probability of trapping holes can be increased by increasing the concentration of the second dopant. However, an increase in the dopant concentration of the light-emitting layer decreases the emission luminance because of a phenomenon called concentration quenching. A means for increasing the probability of trapping holes is exemplified by increasing a hole trap depth instead of increasing the concentration of the dopant in the light emitting layer. Accordingly, in this embodiment, the hole trap depth may be sufficient so as to satisfy formula [5-1] above. When the hole trap depth is sufficient, holes injected into the first light-emitting layer 4a are limited, and a decrease in durability is less likely to proceed. In one embodiment, the trap depth is larger than 0.40 eV as represented by formula [5-1], and in another embodiment is 0.45 eV to 0.50 eV.

### Configuration <3>

The first host and the second host are the same.

In the disclosure, when the first light-emitting layer 4a and the second light-emitting layer 4b are provided as illustrated in FIG. 2A as an example, the first host of the first light-emitting layer 4a and the second host of the second light-emitting layer 4b may be the same material. In addition, the first light-emitting layer 4a and the second light-emitting layer 4b may be formed to be adjacent to each other without another layer such as a charge barrier layer interposed between the light-emitting layers 4a and 4b. This configuration is determined in view of the drive voltage of the element and aimed to eliminate the electrical resistance of the charge barrier layer and to eliminate an increase in the voltage due to the transfer of holes and electrons in the light-emitting layers 4a and 4b to a level of another layer. In the disclosure, among materials contained in the light-emitting layers 4a and 4b, a material having a content of more than 50% by mass in the light-emitting layers 4a and 4b is referred to as a host material, as described above. From the viewpoint of reducing the voltage, the host material may have a high concentration. Accordingly, in one embodiment, the concentration of the host material is 90% by mass or more, and in another embodiment, 95% by mass or more.

The host material is an aromatic hydrocarbon compound that may have an alkyl group having 1 to 12 carbon atoms. The aromatic hydrocarbon compound may include a structure selected from the group consisting of benzene, naphthalene, fluorene, benzofluorene, phenanthrene, chrysene, triphenylene, pyrene, fluoranthene, and benzofluoranthene.

In the organic light-emitting element according to this embodiment, a host material having a band gap wide enough to enable a blue light-emitting dopant material (hereinafter referred to as a “blue dopant”) to emit light is used. Accordingly, the host material may have a high exciton energy when electric charges are recombined and have a structure having high binding energy in the molecule.

Benzene, naphthalene, fluorene, benzofluorene, phenanthrene, chrysene, triphenylene, pyrene, fluoranthene, and benzofluoranthene mentioned above have a structure in which the number of benzene rings linearly fused is up to two and thus have high binding energy in the molecule.

EM1 to EM37 below are specific examples of host materials. Hereinafter, when specific examples of materials are illustrated in the disclosure, the materials are specific examples; however, the materials are not necessarily limited to the illustrated specific examples.

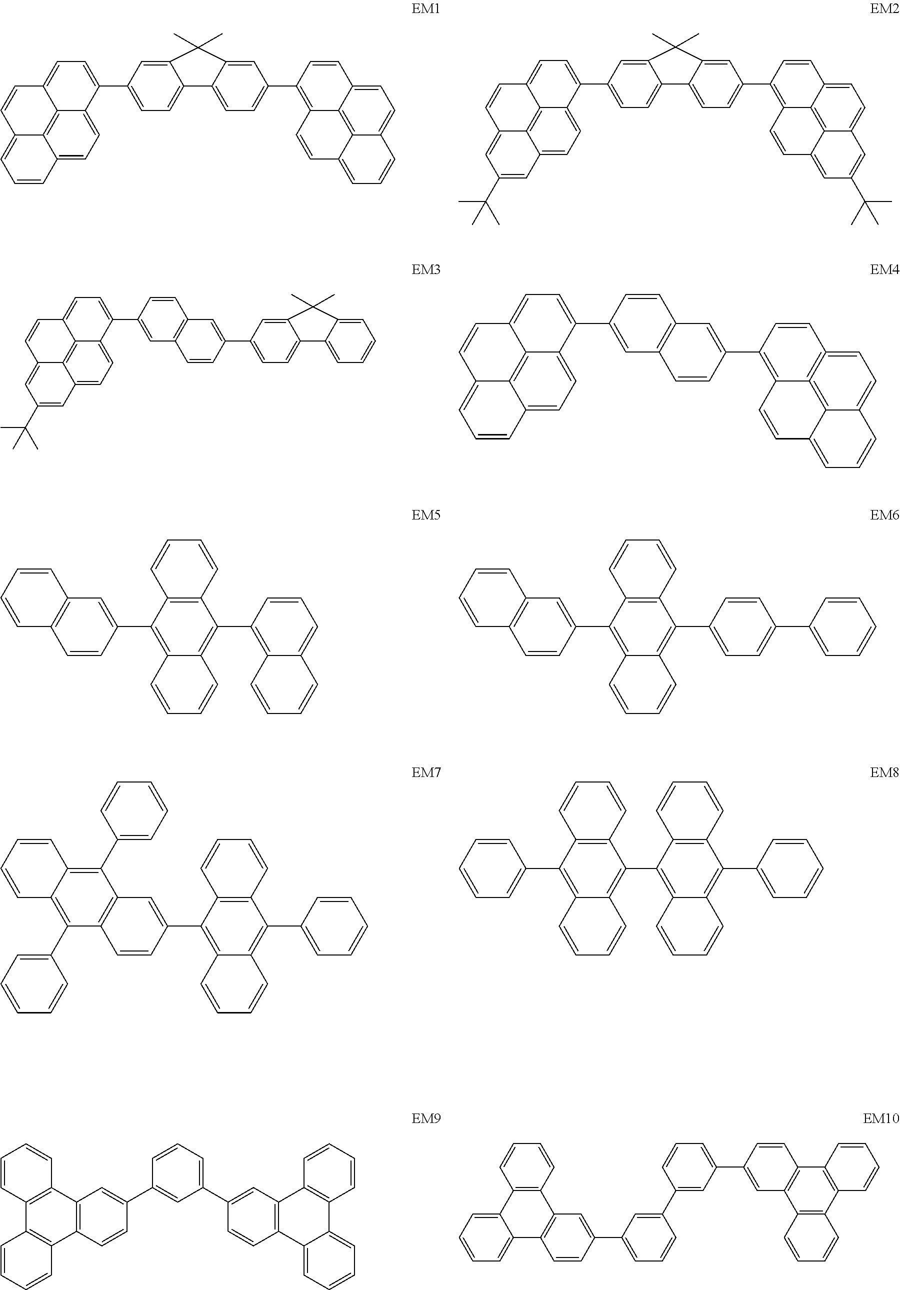

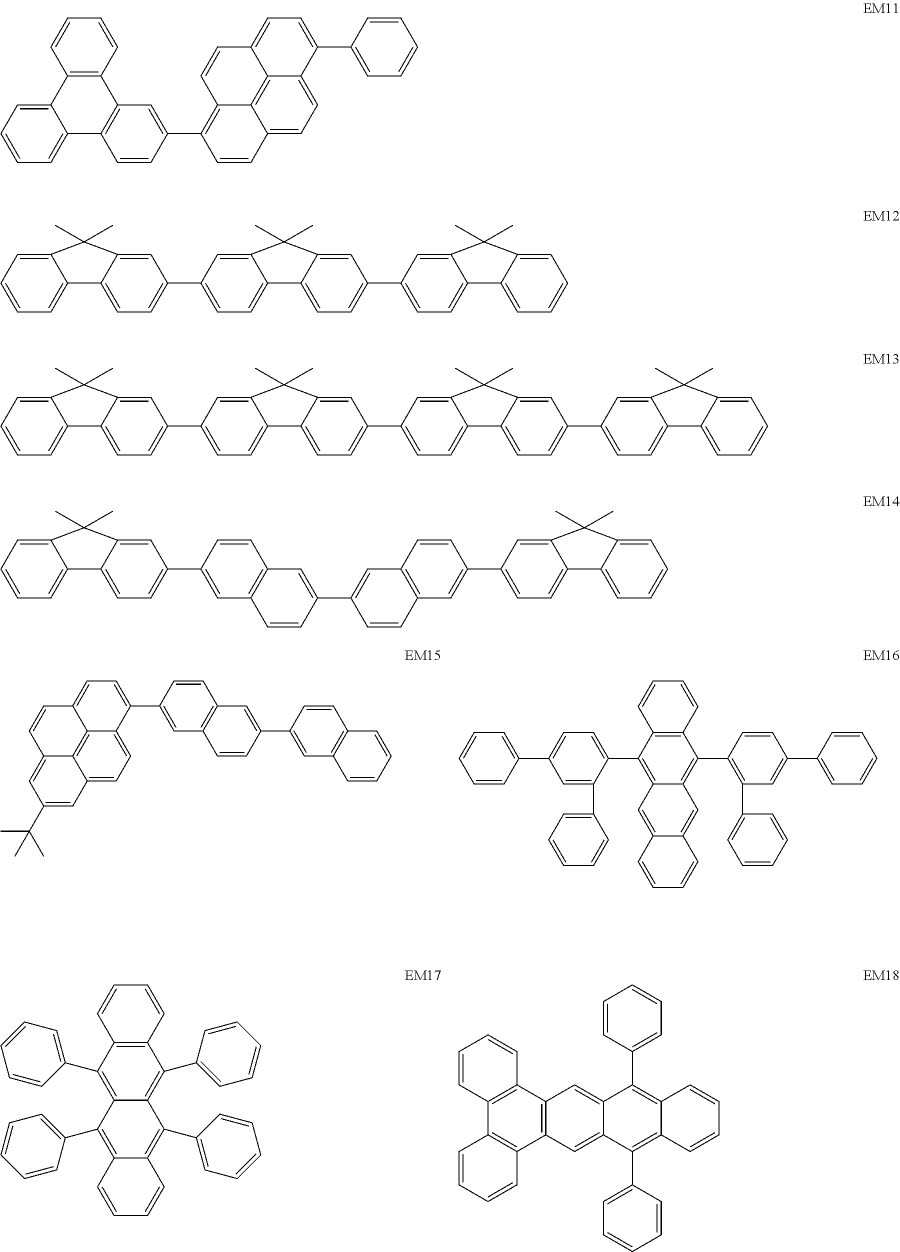

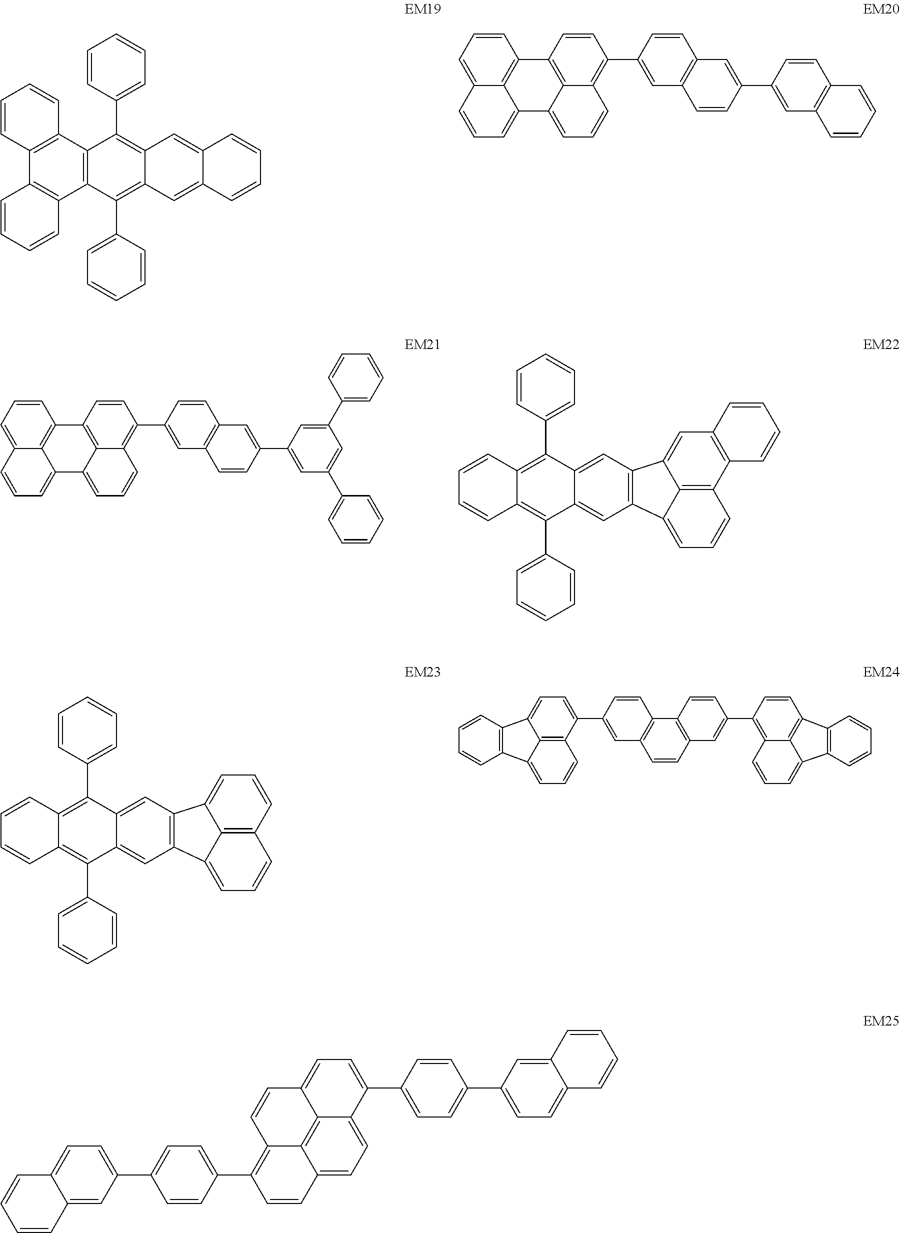

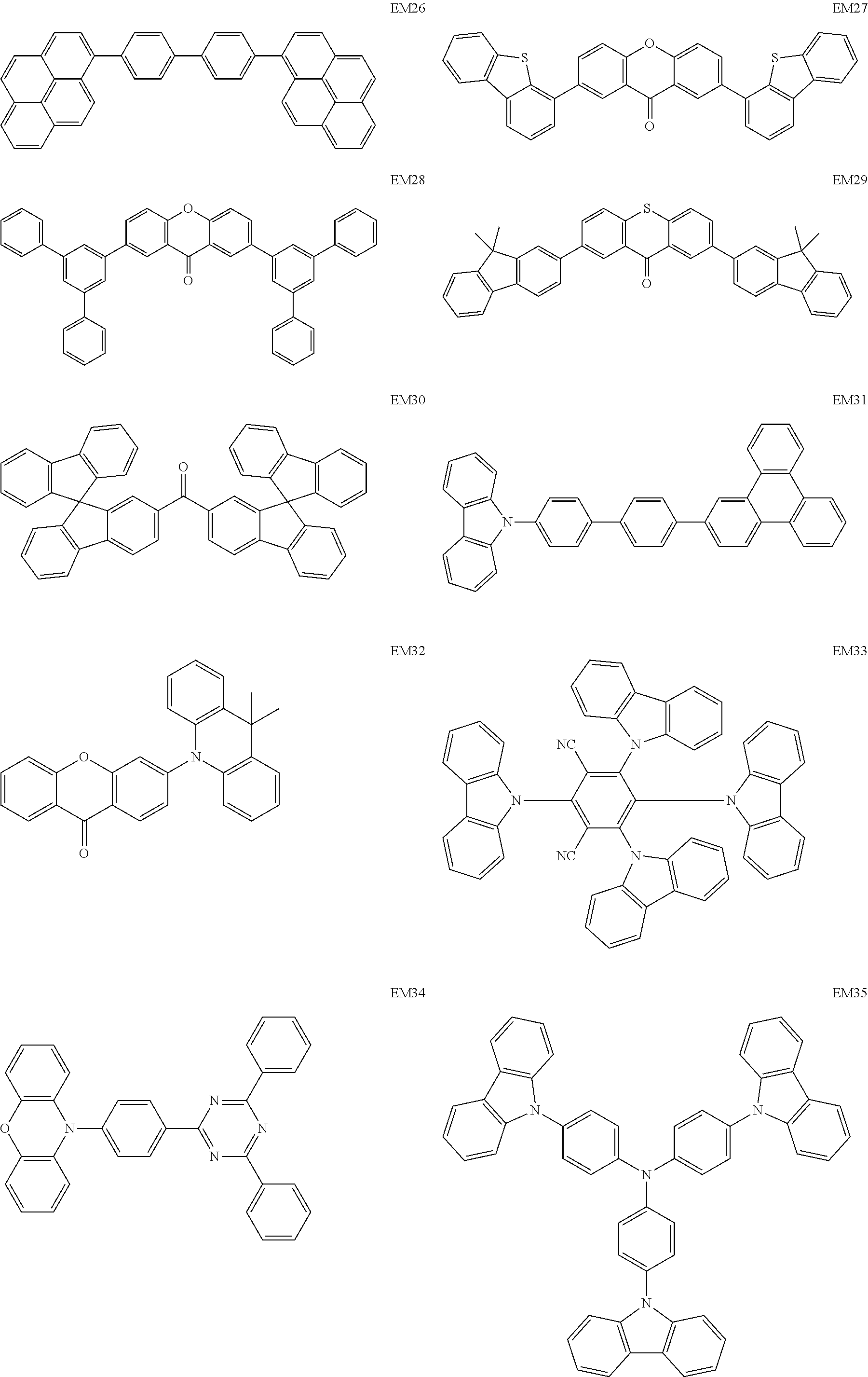

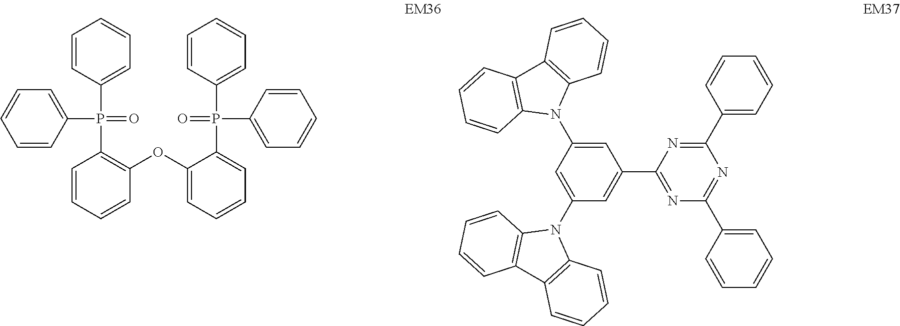 [SMILES: O=P(c1ccccc1)(c1ccccc1)c1ccccc1Oc1ccccc1P(=O)(c1ccccc1)c1ccccc1 ; c1ccc(-c2nc(-c3ccccc3)nc(-c3cc(-n4c5ccccc5c5ccccc54)cc(-n4c5ccccc5c5ccccc54)c3)n2)cc1]

### Configuration <4>

The second light-emitting layer contains a third dopant material (hereinafter referred to as a “third dopant”). The first dopant is a blue dopant, the second dopant is a red light-emitting dopant material (hereinafter referred to as a “red dopant”), and the third dopant is a green light-emitting dopant material (hereinafter referred to as a “green dopant”). Furthermore, when the third dopant has a HOMO level HOMO_{d3} and the second host has a HOMO level HOMOₕ₂ formula [6] below is satisfied.

HOMO_{d3}>HOMOₕ₂ [6]

In the disclosure, when the first light-emitting layer 4a and the second light-emitting layer 4b are provided as illustrated in FIG. 2A as an example, the first light-emitting layer 4a may be a blue-light-emitting layer. In a full-color light-emitting array including organic light-emitting elements, light-emitting materials of three colors of red, green, and, blue are often used. The blue-light-emitting layer has a problem in that a decrease in durability of the element due to hole accumulation is likely to proceed.

Since the first light-emitting layer 4a according to the disclosure has electron trapping properties and hole transporting properties as described above, hole accumulation occurs neither in the light-emitting layer 4a nor at the interface with the functional layer 5. Accordingly, when the first light-emitting layer 4a is the blue-light-emitting layer, a decrease in durability is less likely to occur.

BD1 to BD31 below are specific examples of materials that can be suitably used as light-emitting dopant materials of the blue-light-emitting layer.

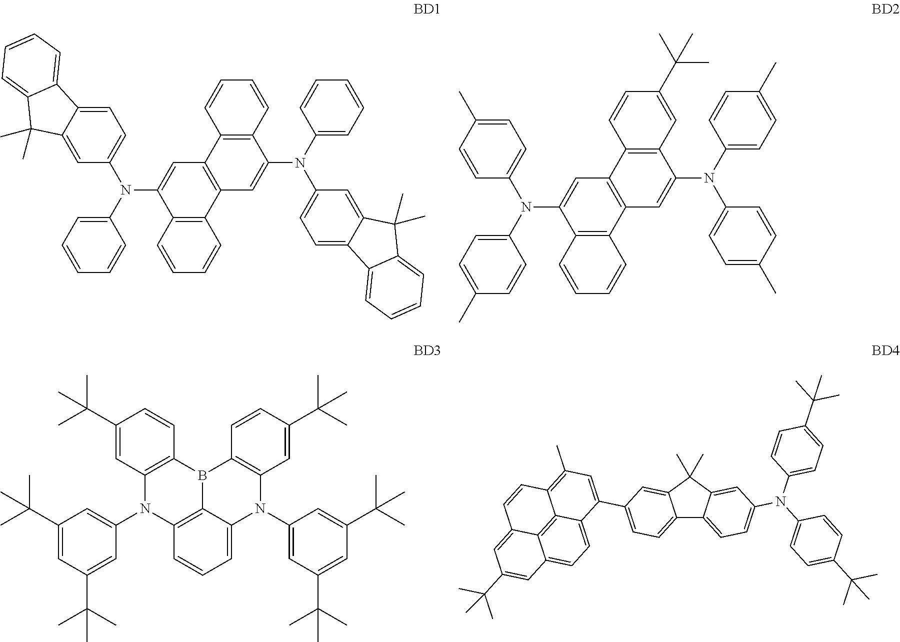

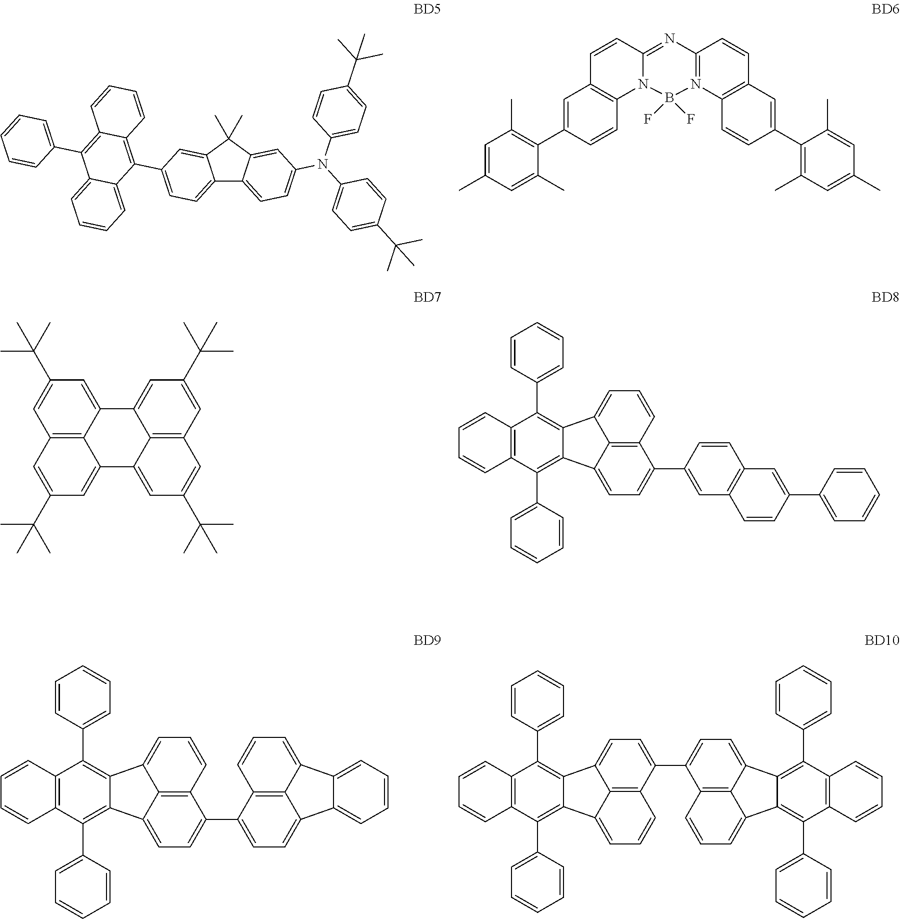

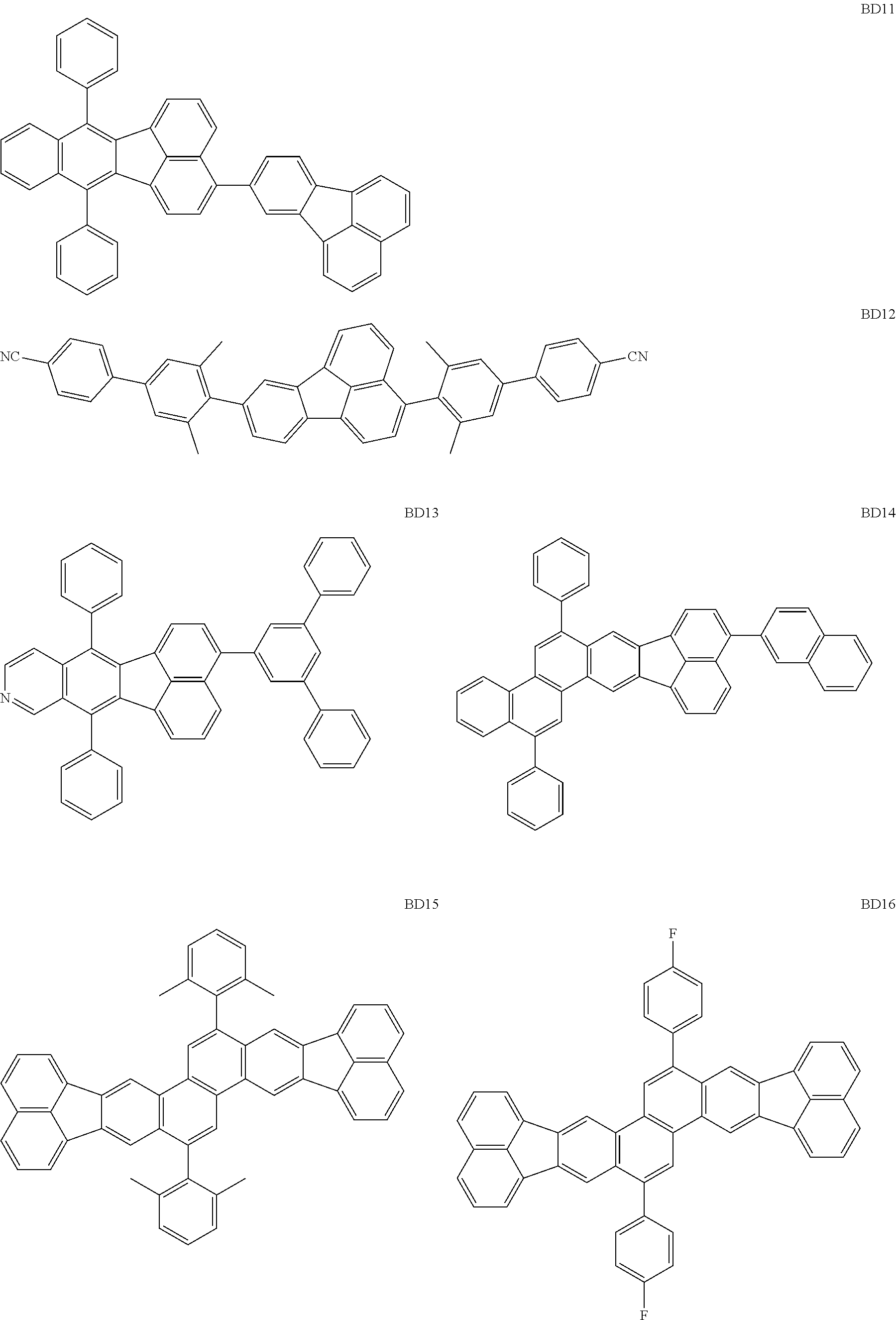

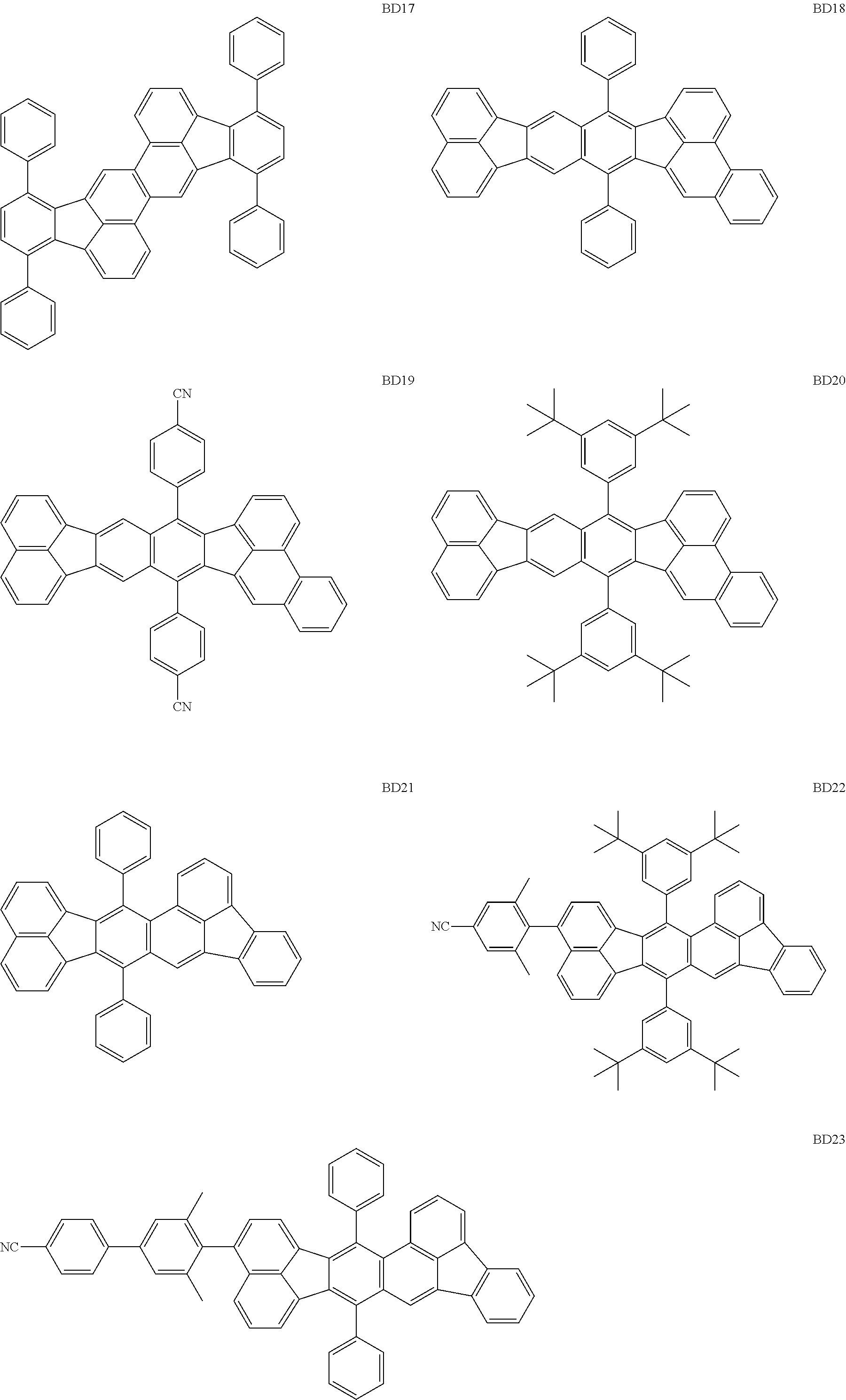

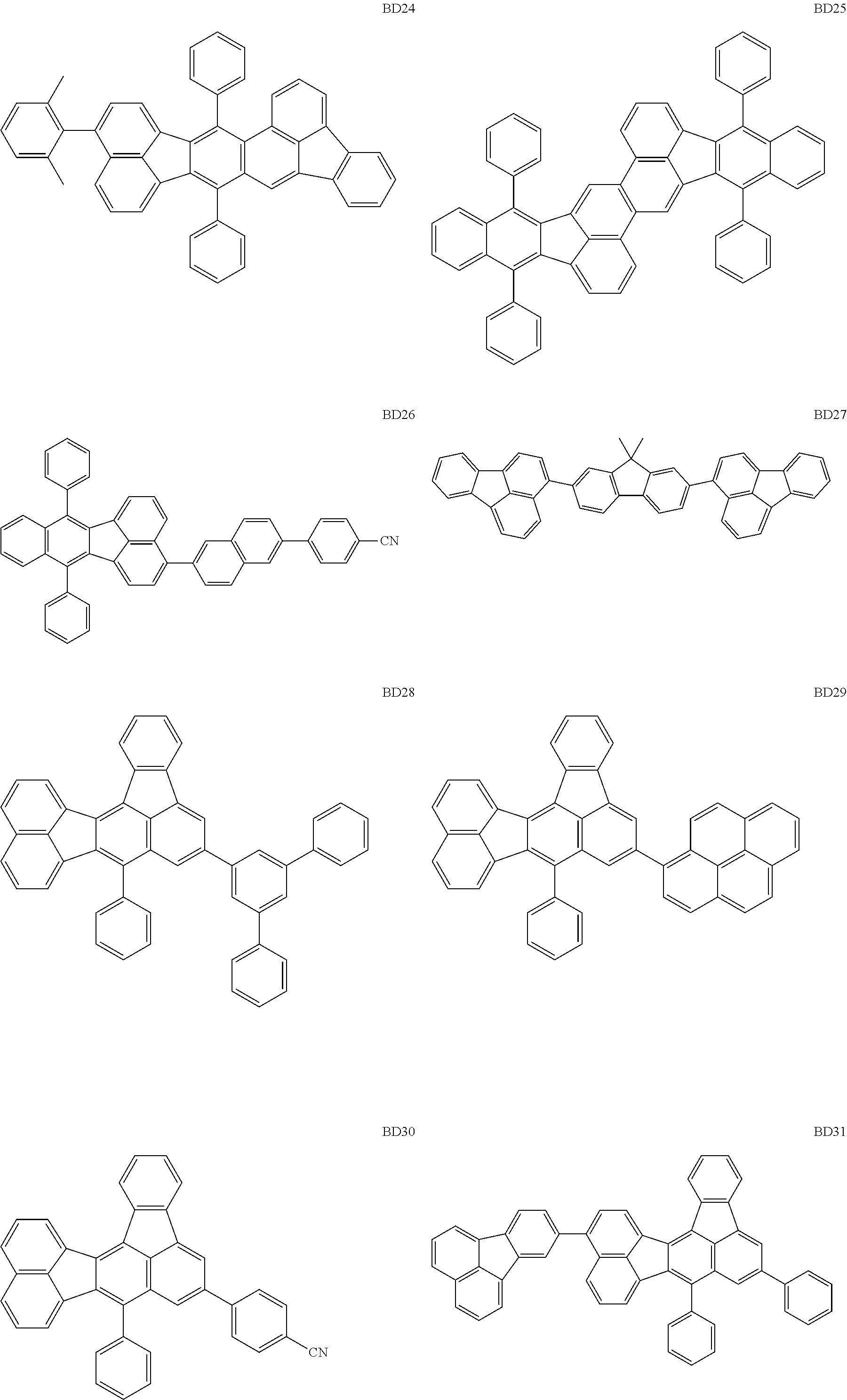

In this embodiment, when the first light-emitting layer 4a is a blue-light-emitting layer, and the second light-emitting layer 4b is a dual-color light-emitting layer of red and green (hereinafter referred to as a “red- and green-light-emitting layer”), a white organic light-emitting element can be provided. In this case, the dual-color light-emitting layer of red and green can be obtained by incorporating a red dopant and a green dopant in the second light-emitting layer 4b.

The second light-emitting layer 4b according to this embodiment satisfies formula [5] above, so that the red dopant traps holes. The second light-emitting layer 4b may further satisfy formula [6] above, so that the green dopant traps holes. Even when the red light-emitting dopant material and the green light-emitting dopant material trap holes, a decrease in durability of the red- and green-light-emitting layer is less likely to proceed than that of the blue-light-emitting layer.

RD1 to RD23 below are specific examples of red dopants, and GD1 to GD32 below are specific examples of green dopants.

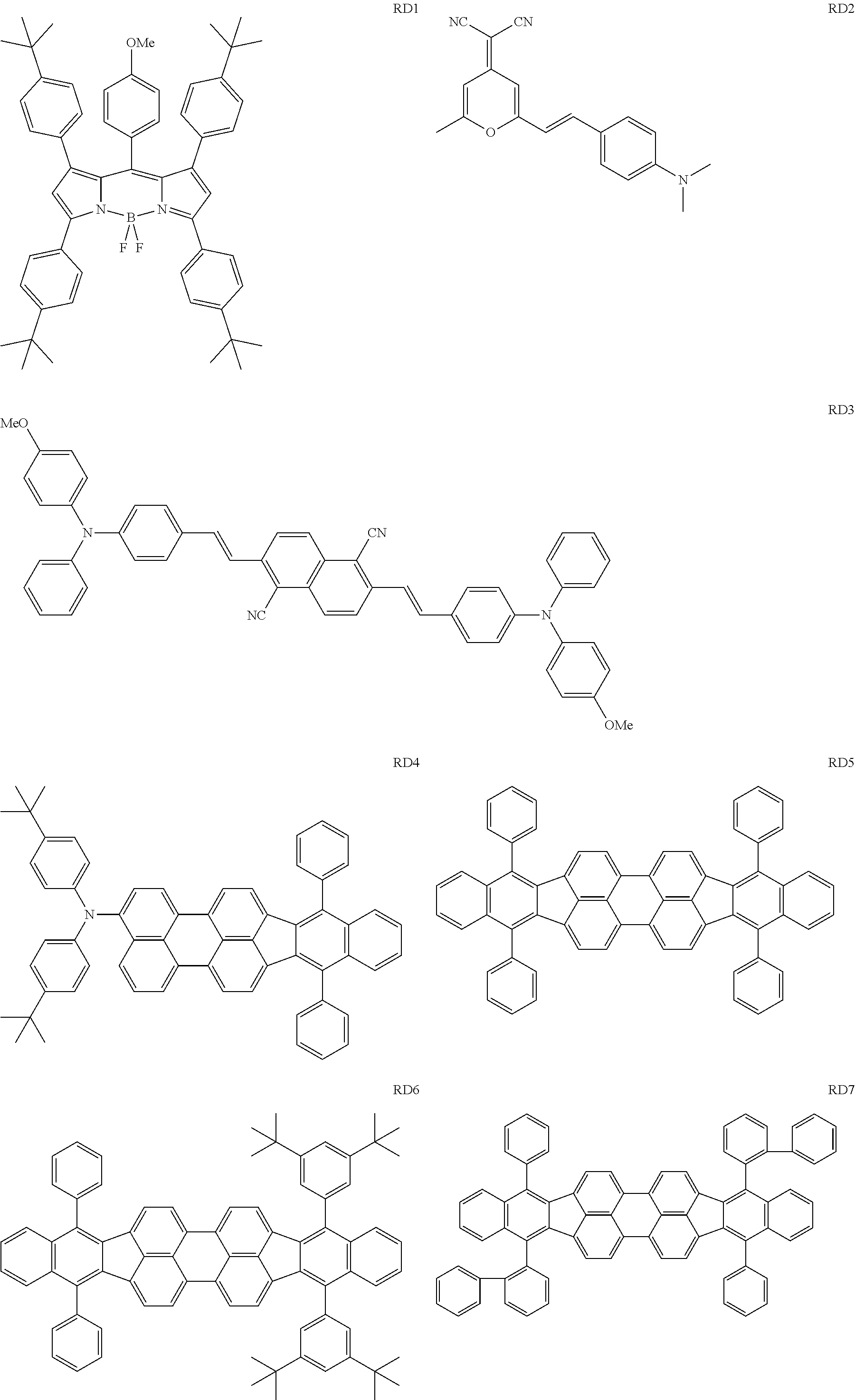

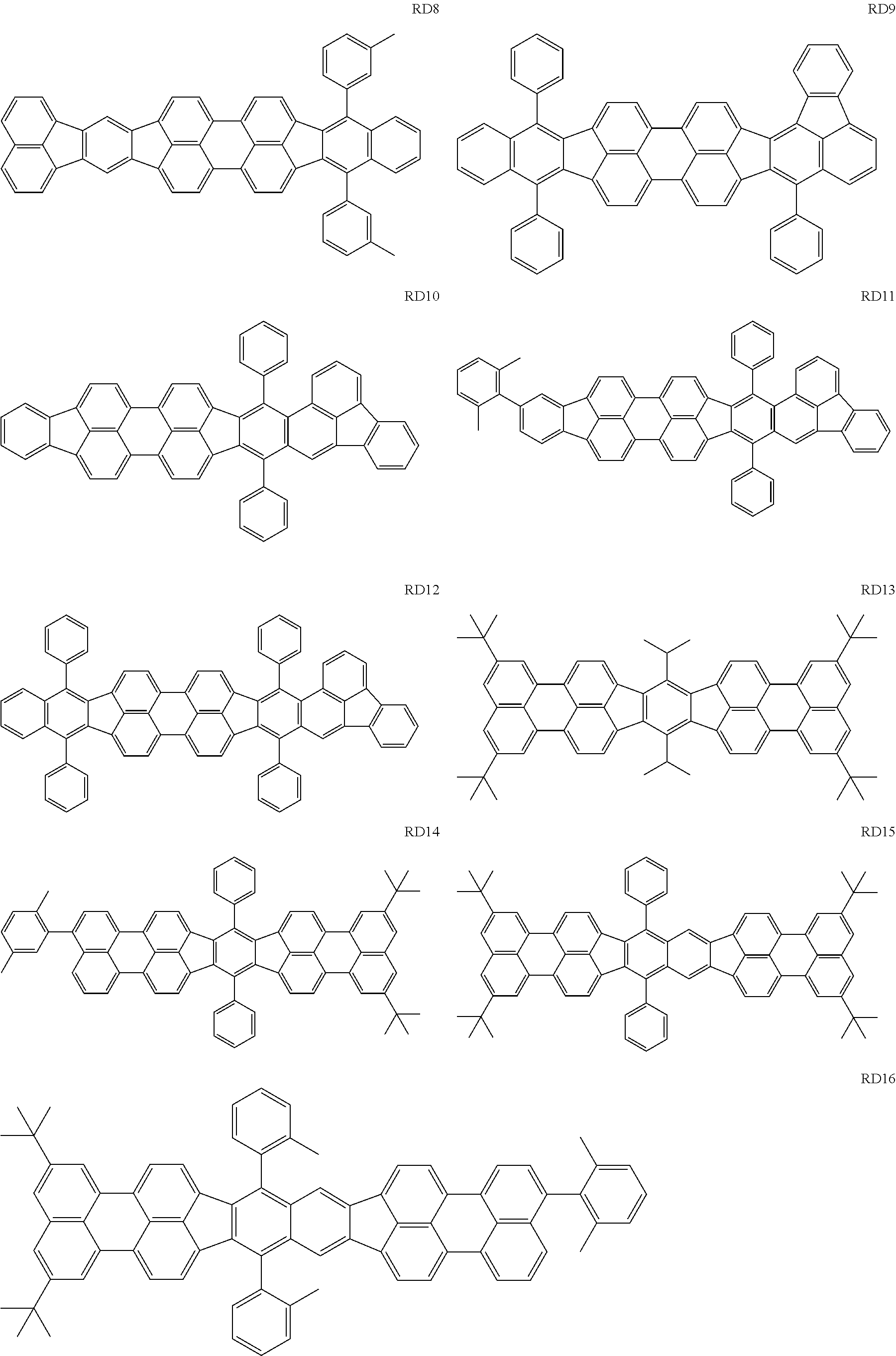

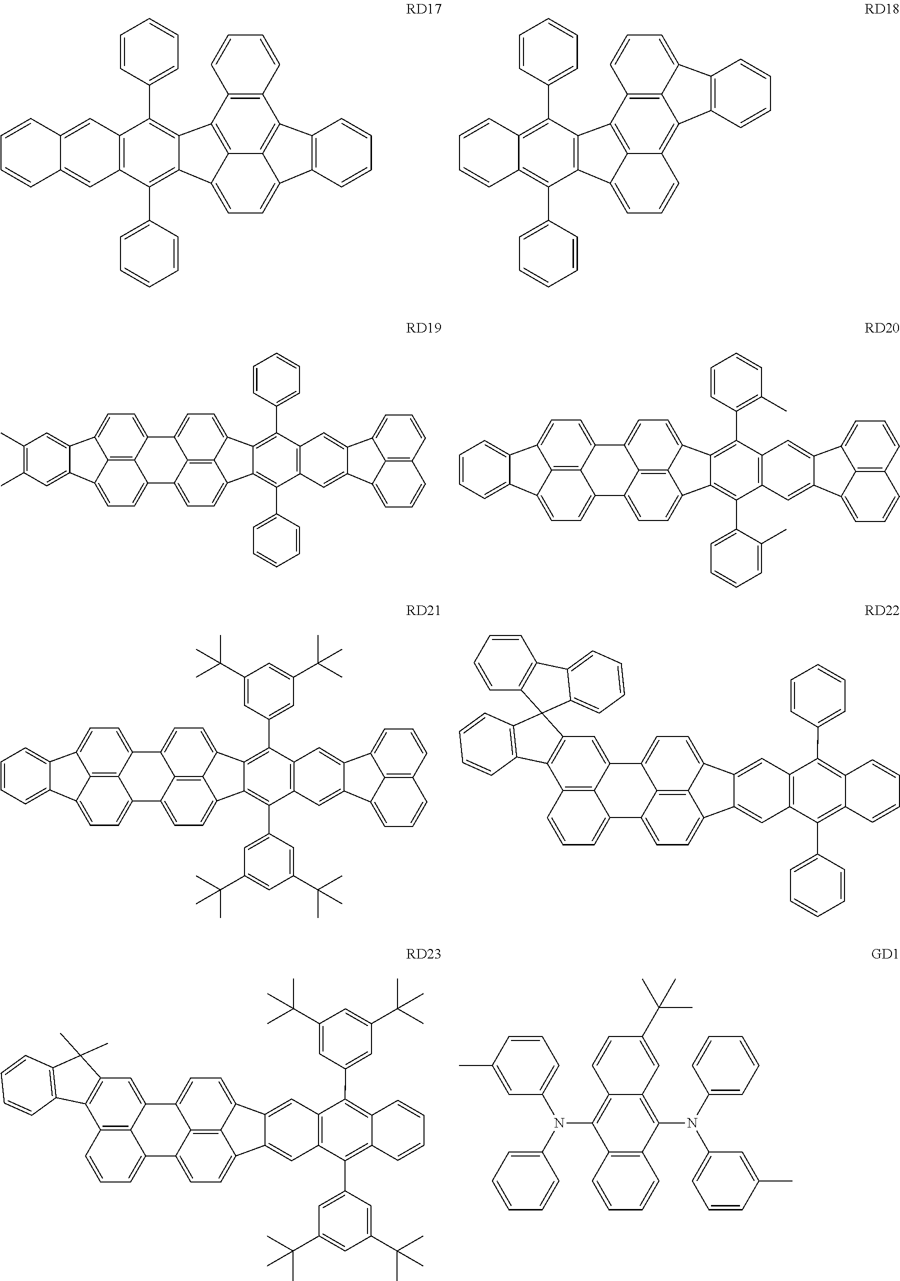

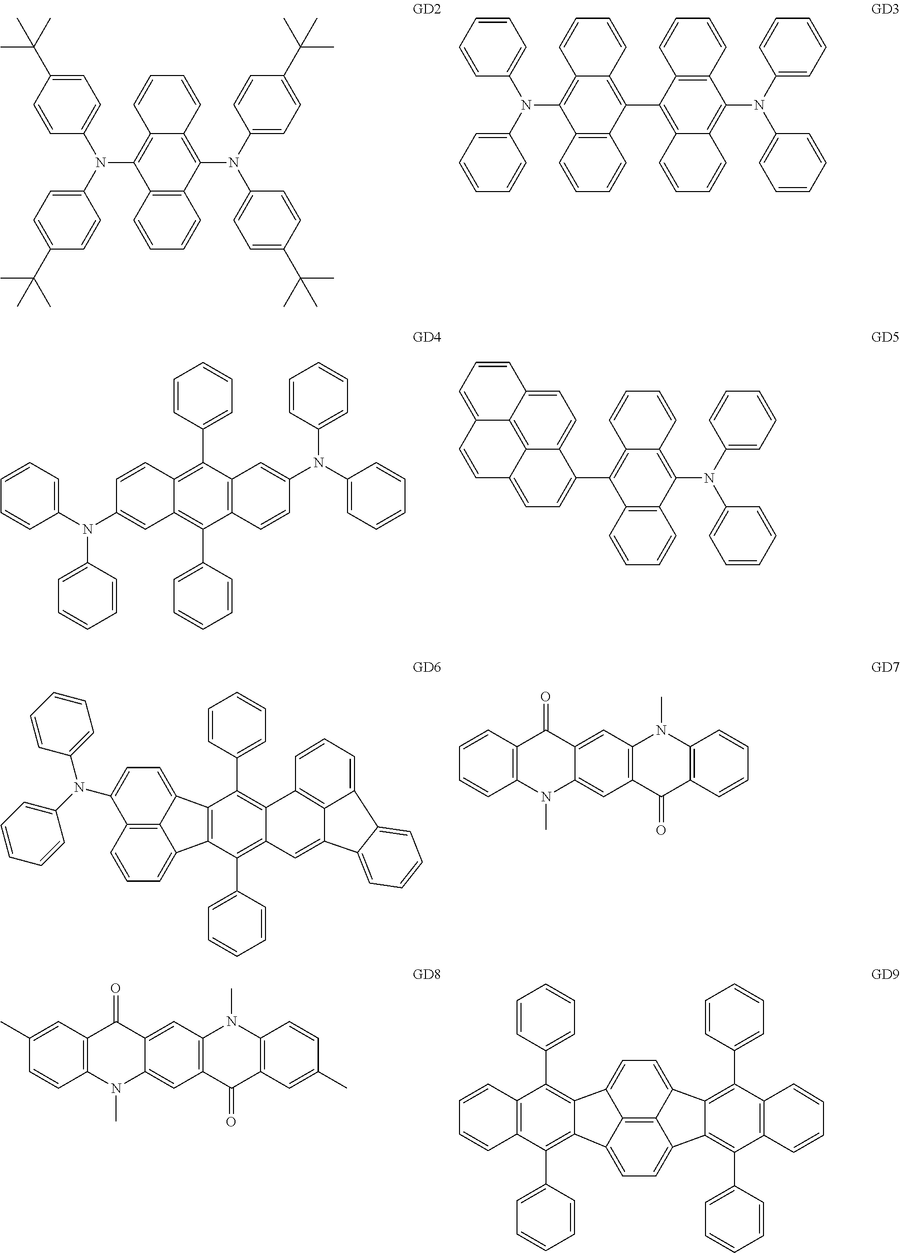

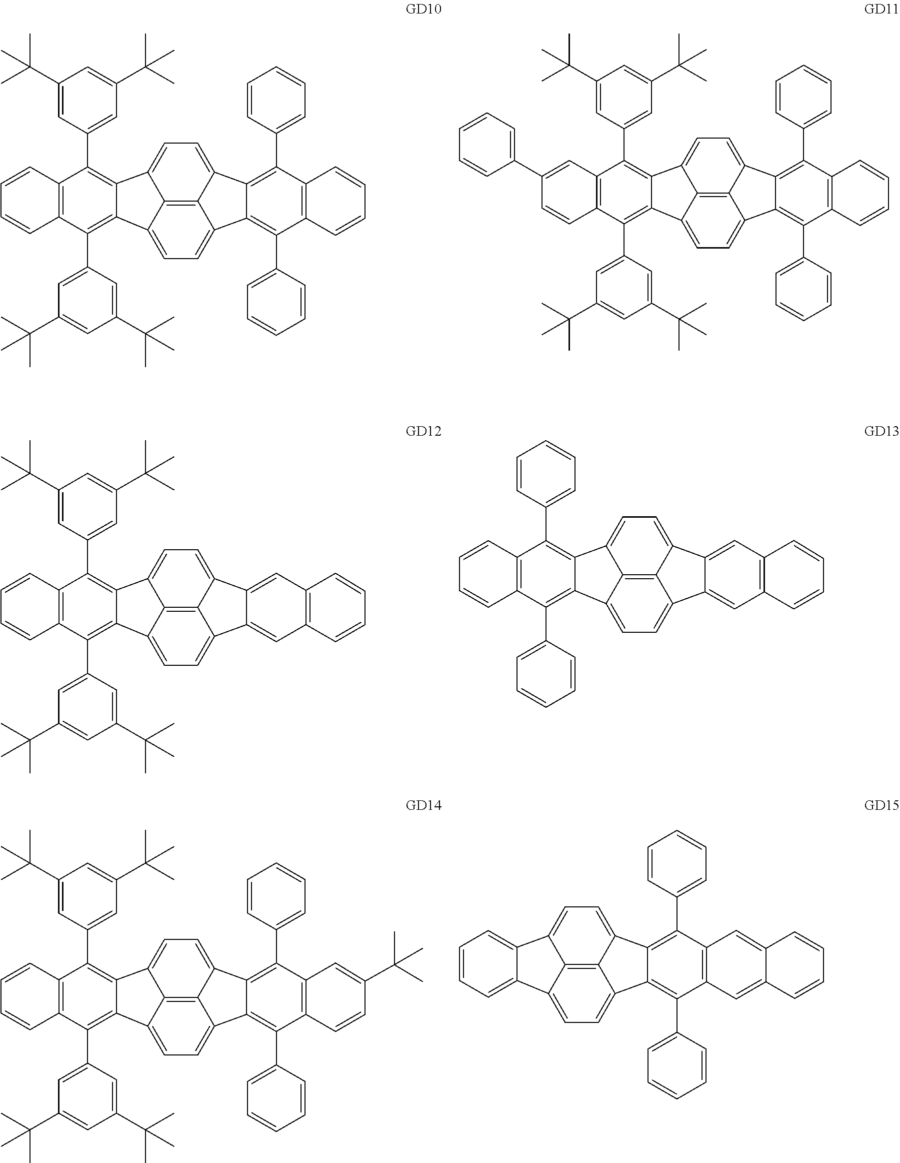

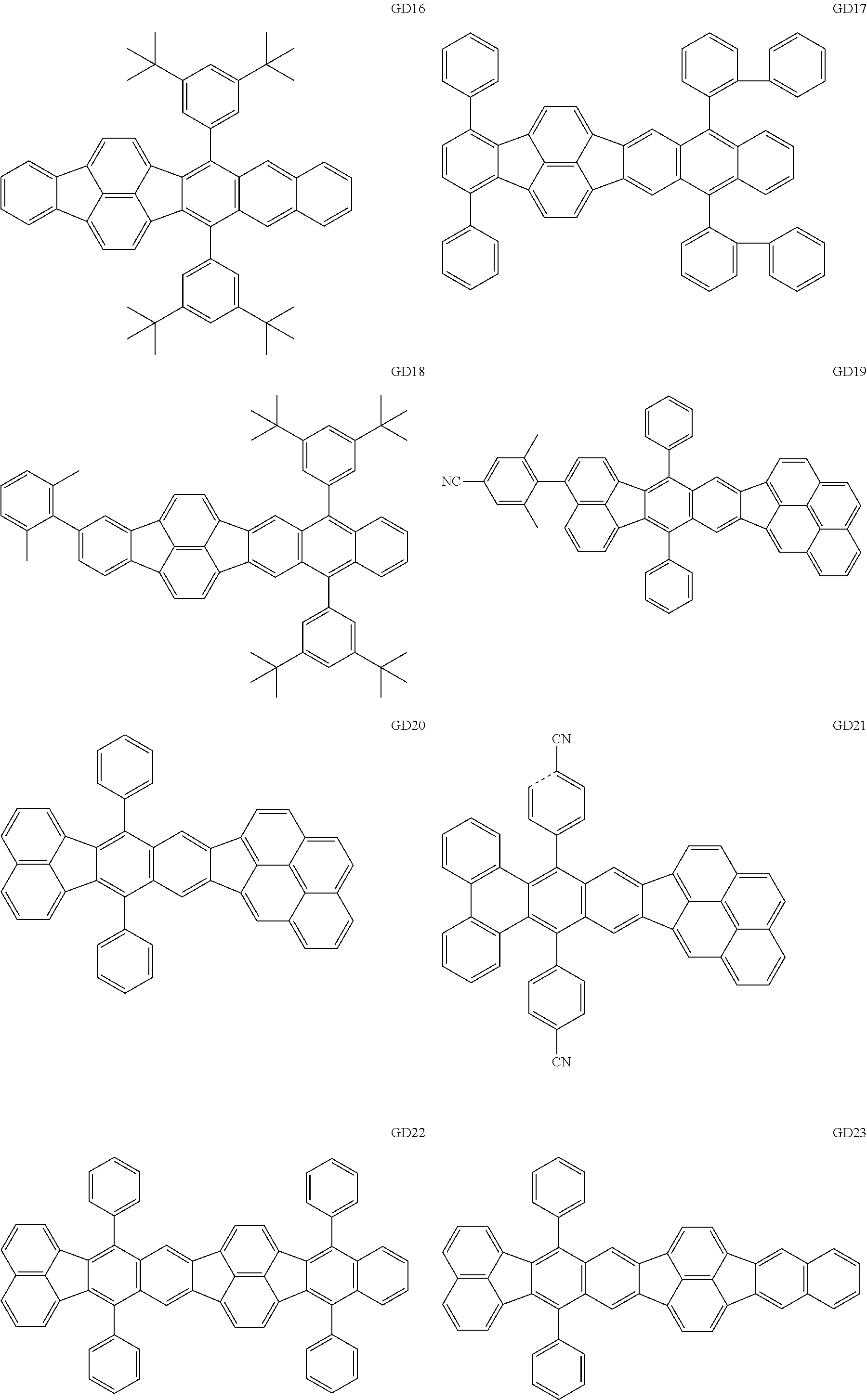

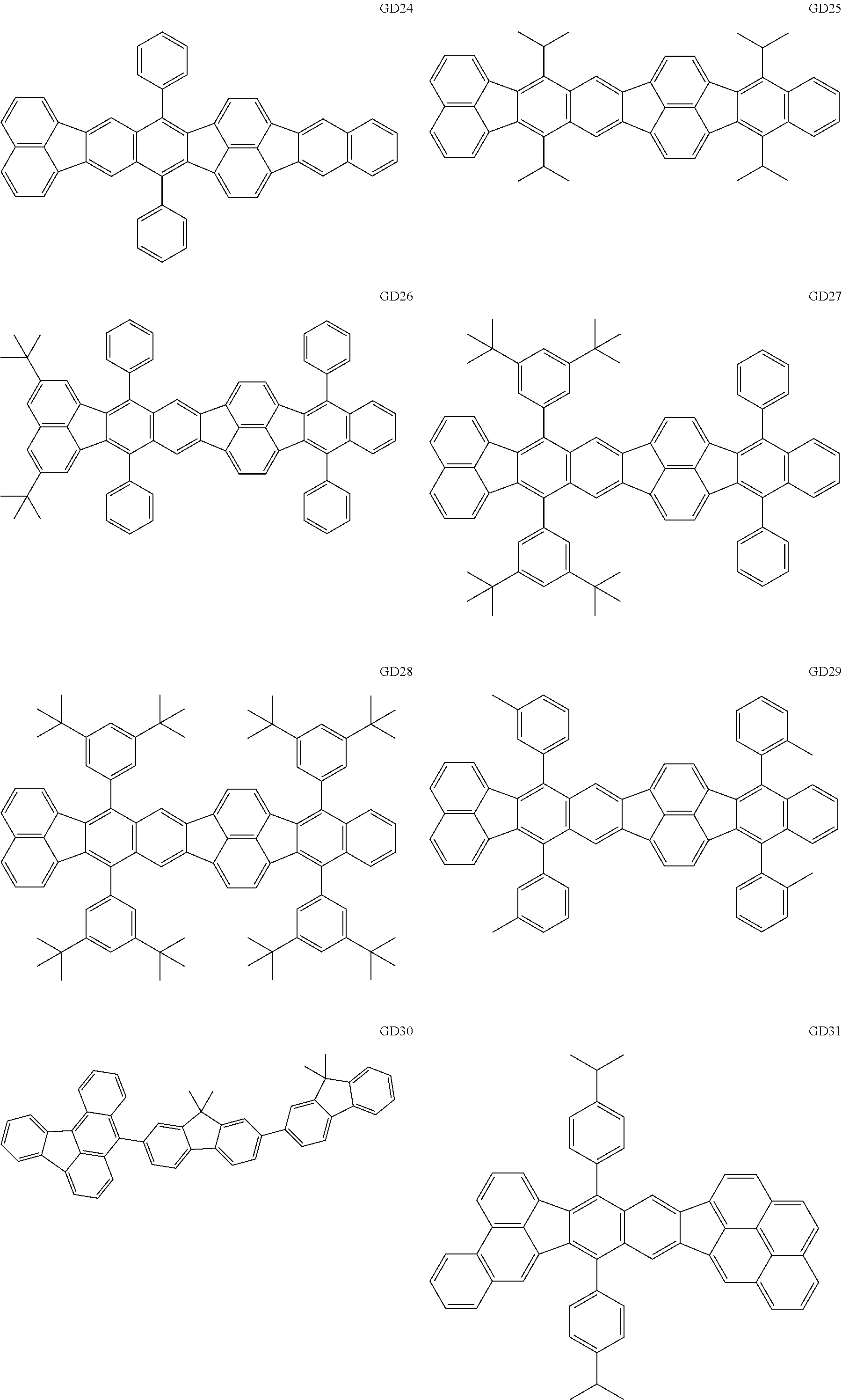

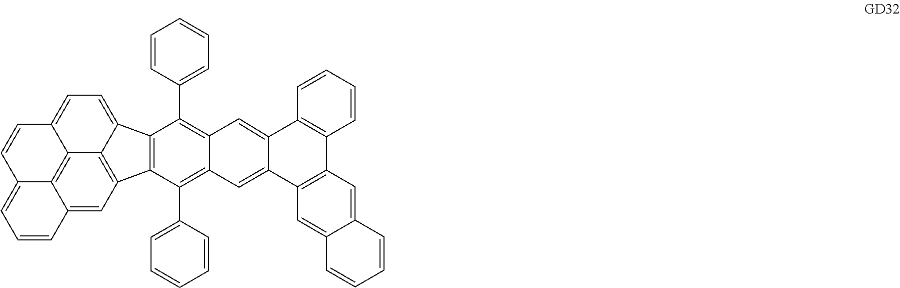 [SMILES: c1ccc(-c2c3c(c(-c4ccccc4)c4cc5c6cc7ccccc7cc6c6ccccc6c5cc24)-c2cc4cccc5ccc6ccc-3c2c6c54)cc1]

In the disclosure, among light components extracted from the organic light-emitting element, a light-emitting component having a maximum emission wavelength of 570 nm to 650 nm is defined as red light, and a light-emitting material that emits the red light is referred to as a red dopant. Similarly, a light-emitting component having a maximum emission wavelength of 490 nm to 540 nm is defined as green light, and a light-emitting material that emits the green light is referred to as a green dopant. Similarly, a light-emitting component having a maximum emission wavelength of 430 nm to 480 nm is defined as blue light, and a light-emitting material that emits the blue light is referred to as a blue dopant.

### Configuration <5>

The organic material that forms the functional layer is composed of a hydrocarbon alone.

Since holes are accumulated in the functional layer 5 according to the disclosure, the functional layer 5 may have a molecular structure that can withstand the generation of excessive radical cations and may be composed of a hydrocarbon having high chemical stability. When the functional layer 5 is composed of a hydrocarbon alone, the functional layer 5 contains a compound that does not have a bond having low binding stability in the molecular structure. Such a compound is unlikely to deteriorate during driving of the element to provide an organic light-emitting element having a long life.

The bond having low binding stability in the molecular structure refers to a bond that has a relatively low binding energy and is unstable, as in the case of an amino group.

In compounds A-1, A-2, and B-1 shown below, the bond having low binding stability is the bond linking a carbazole ring to a phenylene group and the bond linking an amino group to a phenyl group (nitrogen-carbon bonds). The bond linking carbon to carbon as shown in compound B-1 has higher binding stability. These results were obtained using a calculation technique of b3-lyp/def2-SV(P).

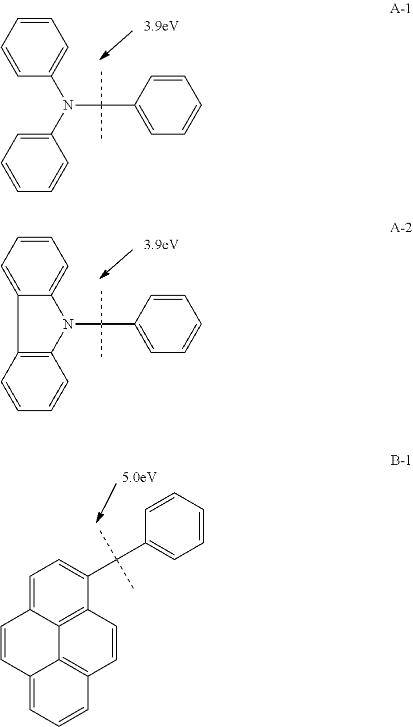

According to the above results, the material that forms the functional layer 5 according to the disclosure can be constituted by a material composed of a hydrocarbon alone. Specifically, benzene, naphthalene, fluorene, benzofluorene, phenanthrene, chrysene, triphenylene, pyrene, fluoranthene, and benzofluoranthene can be included because they have a structure in which the number of benzene rings linearly fused is up to two and thus have high binding energy in the molecule.

FL1 to FL24 below are specific examples of materials that can be suitably used as the functional layer 5.

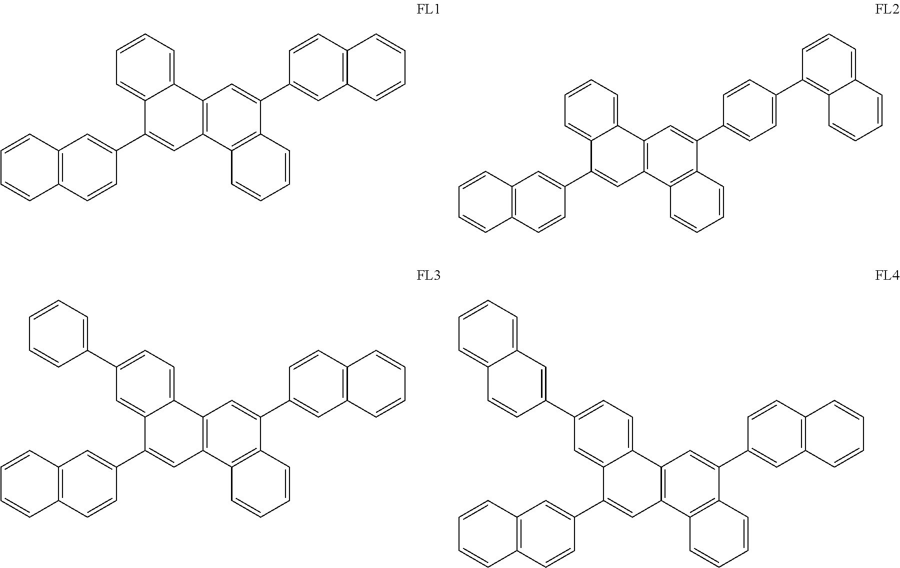

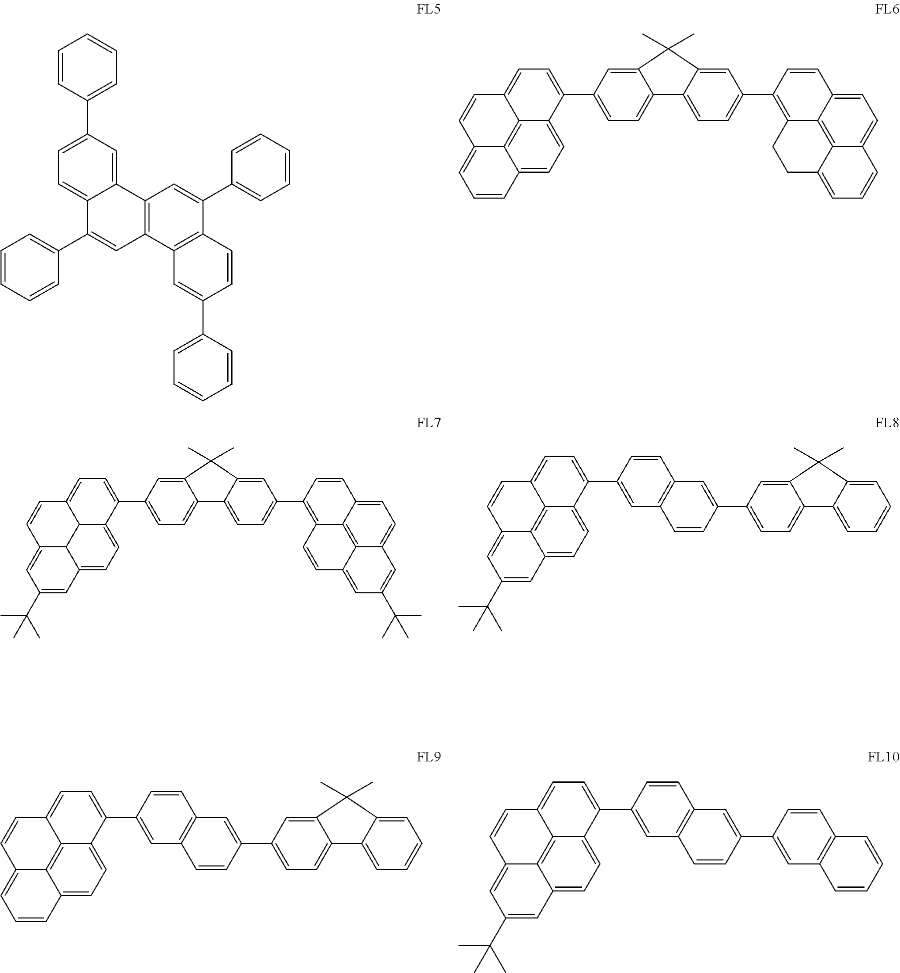

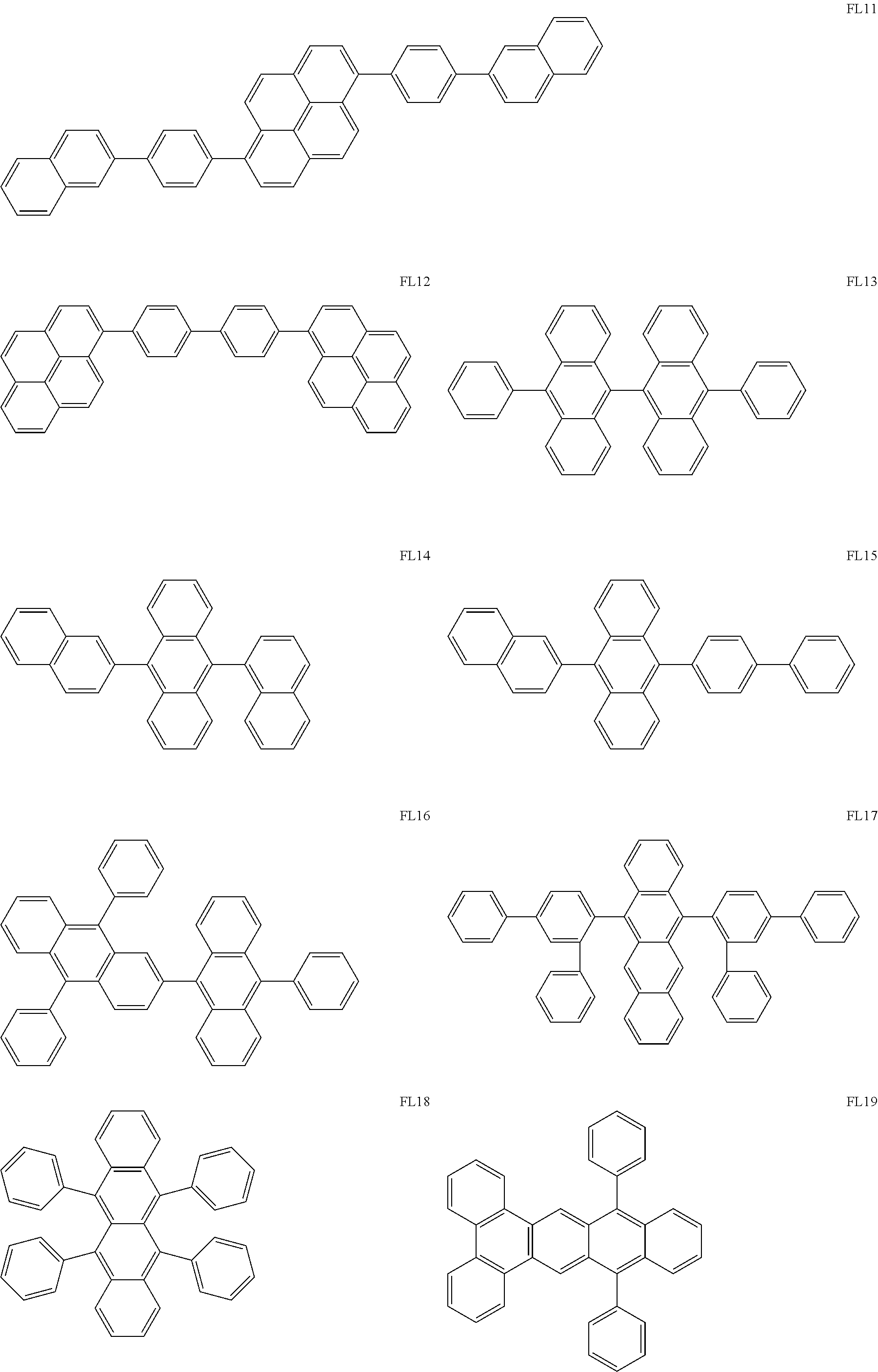

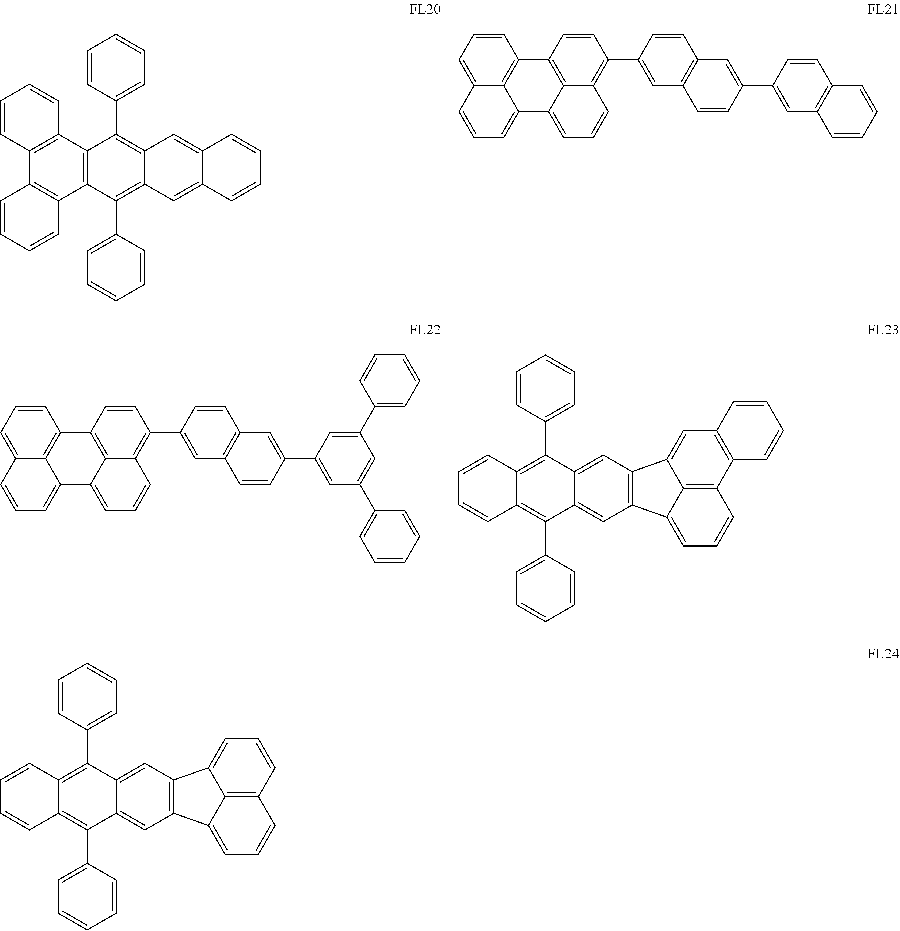

### Configuration <6>

An electron transport layer composed of an organic material is provided on the cathode side of the functional layer while being in contact with the functional layer. When the organic material that forms the functional layer has a HOMO level HOMO_{FL} and the organic material that forms the electron transport layer has a HOMO level HOMO_{ETL}, formula [7] below is satisfied.

HOMO_{FL}>HOMO_{ETL} [7]

Since formula [7] is satisfied, electrons are injected from the electron transport layer 6 to the functional layer 5 without a barrier. Holes are also injected from the first light-emitting layer 4a to the functional layer 5 without a barrier, and thus the accumulation of holes occurs in the functional layer 5, and holes and electrons that have failed to recombine in the first light-emitting layer 4a recombine in the functional layer 5. Accordingly, since the accumulation of holes occurs in the functional layer 5, durability of the light-emitting layer 4a can be prevented from being decreased by hole accumulation.

The material used in the electron transport layer 6 may be selected from any material capable of transporting electrons injected from the cathode 7 to the first light-emitting layer 4a and is selected in consideration of, for example, the balance with the hole mobility of a hole-transporting material. Such a material may also be used in the hole blocking layer and the electron injection layer. Examples of materials having electron transporting properties include oxadiazole derivatives, oxazole derivatives, pyrazine derivatives, triazole derivatives, triazine derivatives, quinoline derivatives, quinoxaline derivatives, and phenanthroline derivatives.

ET1 to ET16 below are specific examples of materials that can be suitably used in the electron transport layer 6.

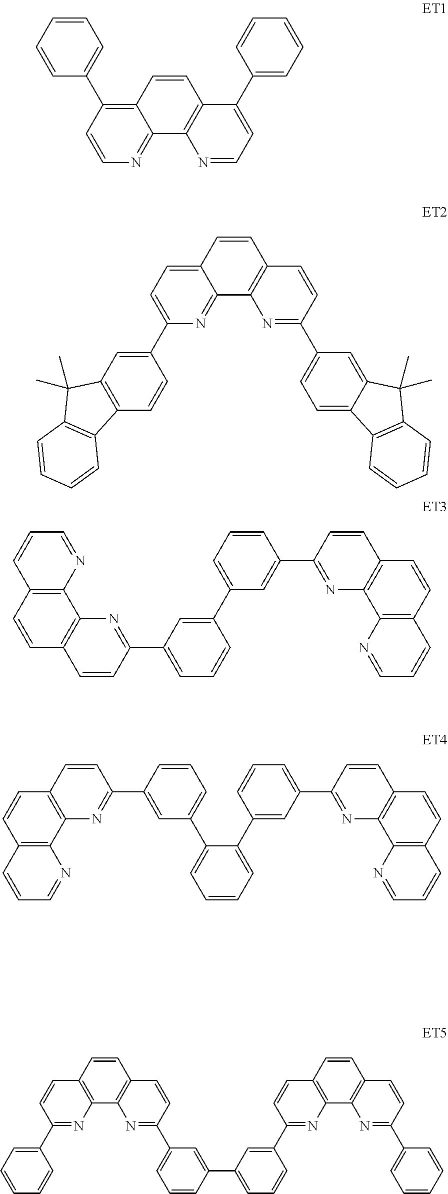

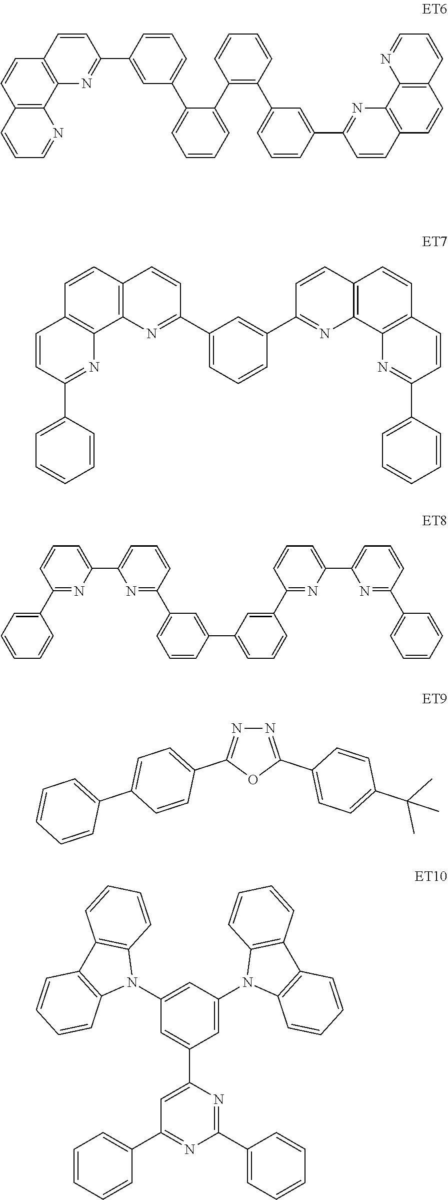 [SMILES: c1cc(-c2ccc3ccc4cccnc4c3n2)cc(-c2ccccc2-c2ccccc2-c2cccc(-c3ccc4ccc5cccnc5c4n3)c2)c1 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cccc(-c3cccc(-c4cccc(-c5cccc(-c6cccc(-c7cccc(-c8ccccc8)n7)n6)c5)c4)n3)n2)cc1 ; CC(C)(C)c1ccc(-c2nnc(-c3ccc(-c4ccccc4)cc3)o2)cc1 ; c1ccc(-c2cc(-c3cc(-n4c5ccccc5c5ccccc54)cc(-n4c5ccccc5c5ccccc54)c3)nc(-c3ccccc3)n2)cc1]

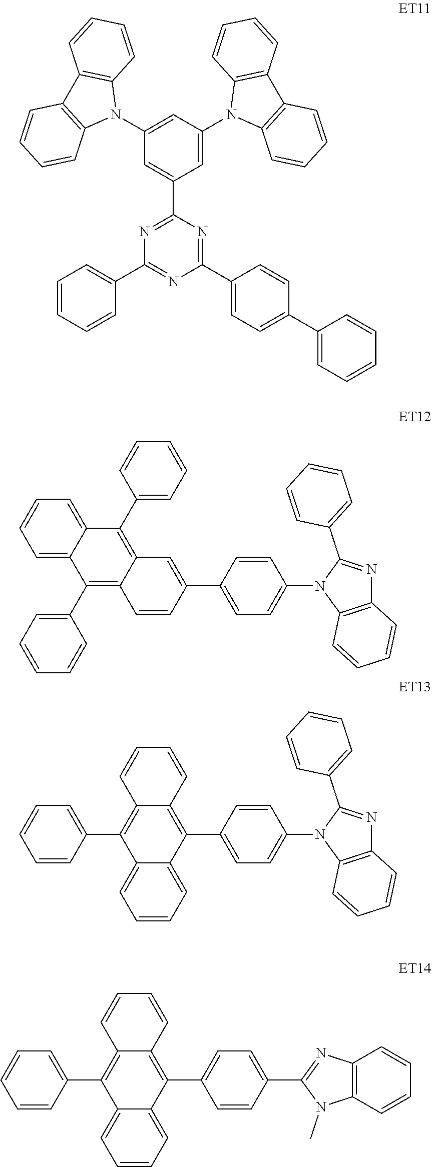 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1 ; Cn1c(-c2ccc(-c3c4ccccc4c(-c4ccccc4)c4ccccc34)cc2)nc2ccccc21]

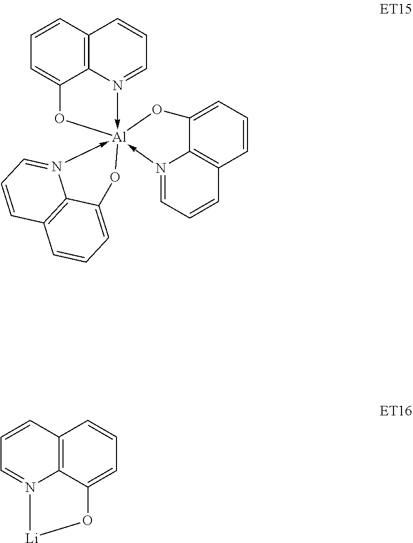

### Other Components of Organic Light-Emitting Element

Other components of the organic light-emitting element according to the disclosure will be described.

### Substrate

The organic light-emitting element according to the disclosure may include a substrate 1 as illustrated in FIGS. 1A and 2A. The substrate 1 may be a silicon substrate, a glass substrate, or a resin substrate. In the case of using the silicon substrate, a micro-display apparatus can also be provided by forming transistors in the silicon substrate itself. In the case of using the glass substrate, a display apparatus may be provided by forming TFTs. The resin substrate may also be referred to as a flexible substrate. In the case of using the flexible substrate, a foldable or rollable display apparatus may be provided. The substrate may be optically transparent or opaque as long as the substrate does not block the emission direction of the light-emitting apparatus.

### Electrodes

The organic light-emitting element according to the disclosure includes the anode 2 and the cathode 7. The anode 2 may be a reflective electrode, and the cathode 7 may be a transmissive electrode. Alternatively, each of the anode 2 and the cathode 7 may be a transmissive electrode, or the anode 2 may be a transmissive electrode and the cathode 7 may be a reflective electrode.

The reflective electrode may be made of a metal material having a reflectance of 80% or more. Specifically, the material of the reflective electrode may be a metal such as Al or Ag or an alloy obtained by adding Si, Cu, Ni, Nd, Ti, or the like to such a metal. For example, AgMg, AlCu, or TiN can be used as the alloy. The term reflectance refers to a reflectance at a wavelength of light emitted from the light-emitting layer. The reflective electrode may have a barrier layer on the surface on the light extraction side thereof. The material of the barrier layer may be a metal such as Ti, W, Mo, or Au or an alloy thereof. The alloy may encompass any of the alloys mentioned above.

The transmissive electrode may be composed of a conductive metal oxide such as ITO or IZO or may be a semi-transmissive metal layer. When the transmissive electrode is the cathode, the electrode is formed of, for example, an alloy containing magnesium or silver as a main component, or an alloy material containing an alkali metal or an alkaline earth metal. The transmissive electrode may have a multilayered structure provided that the electrode has a suitable transmittance.

The electrodes can be formed by, for example, a sputtering method or a vacuum evaporation method.

### Organic Compound Layers

The organic light-emitting element according to the disclosure may include, for example, a hole injection layer, an electron blocking layer, and an electron injection layer besides the components illustrated in FIGS. 1A and 2A and may include a plurality of layers serving as any of these layers. These layers may be composed of an inorganic compound.

The organic light-emitting element may have various layer configurations. For example, the organic light-emitting element may further include an insulating layer disposed at an interface between the electrode 2 or 7 and an organic compound layer or include an adhesion layer or an interference layer. The electron transport layer 6 or the hole transport layer 3 may be formed of two layers having different ionization potentials.

The organic compound layer according to the disclosure may be formed as a common layer shared by a plurality of organic light-emitting elements. The common layer refers to a layer disposed to extend over a plurality of organic light-emitting elements and may be formed by a coating method, such as spin coating, or vapor deposition method for the entire surface of the substrate.

Examples of the materials of the organic compound layers will be described below. The material used in the hole transport layer 3 may be a material capable of facilitating injection of holes from the anode 2 or a material having a high hole mobility so that the injected holes can be transported to the light-emitting layers 4a and 4b. The hole injection layer and the electron blocking layer can also be formed by using similar materials.

To reduce deterioration of the film quality, such as crystallization, in the organic light-emitting element, a material having a high glass transition temperature may be used. Examples of low-molecular-weight or high-molecular-weight materials having a high hole mobility include triarylamine derivatives, aryl carbazole derivatives, phenylenediamine derivatives, stilbene derivatives, phthalocyanine derivatives, porphyrin derivatives, poly(vinylcarbazole), poly(thiophene), and other electrically conductive polymers.

HT1 to HT19 below are specific examples of the material used in the hole transport layer 3, but the material is not limited to these.

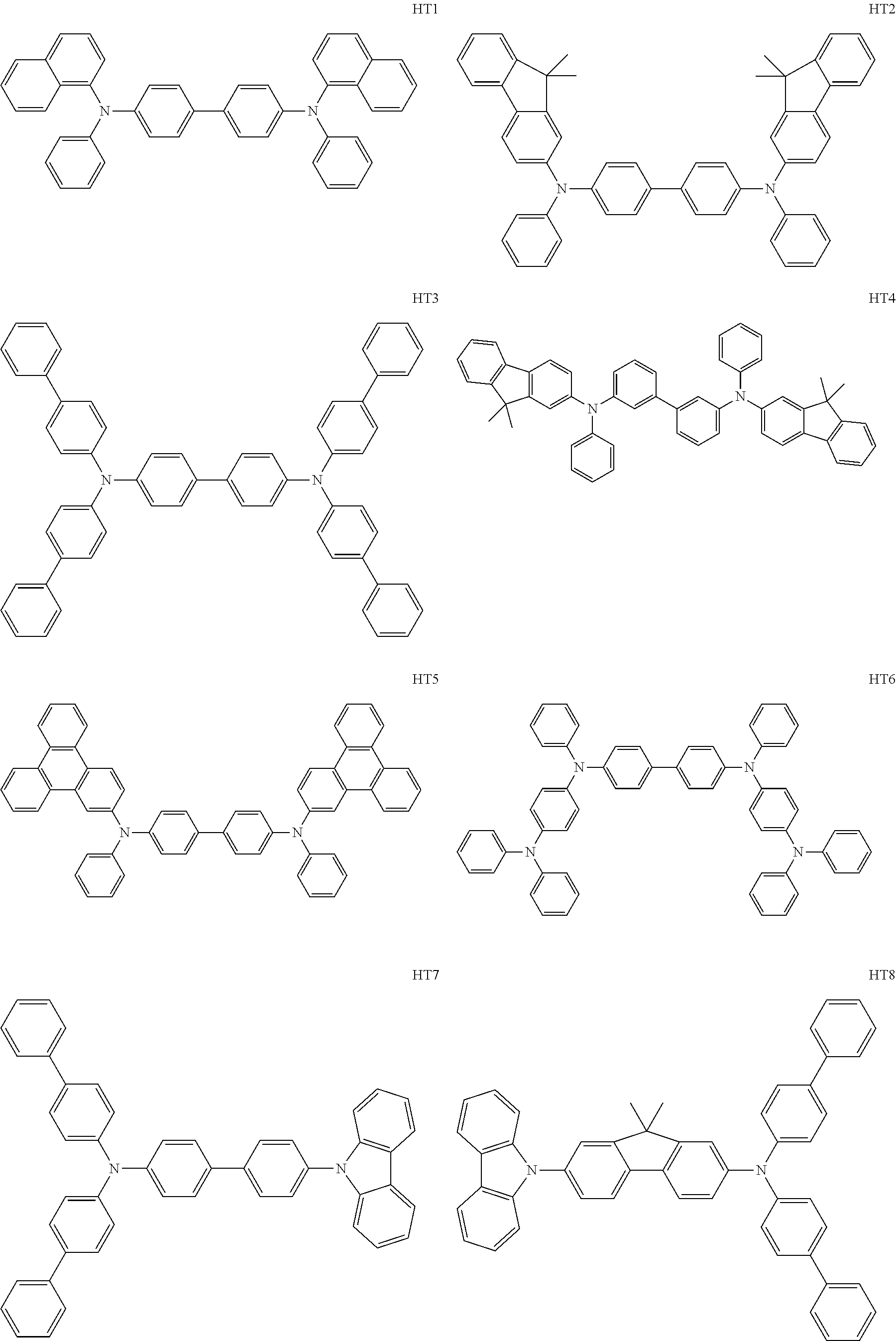

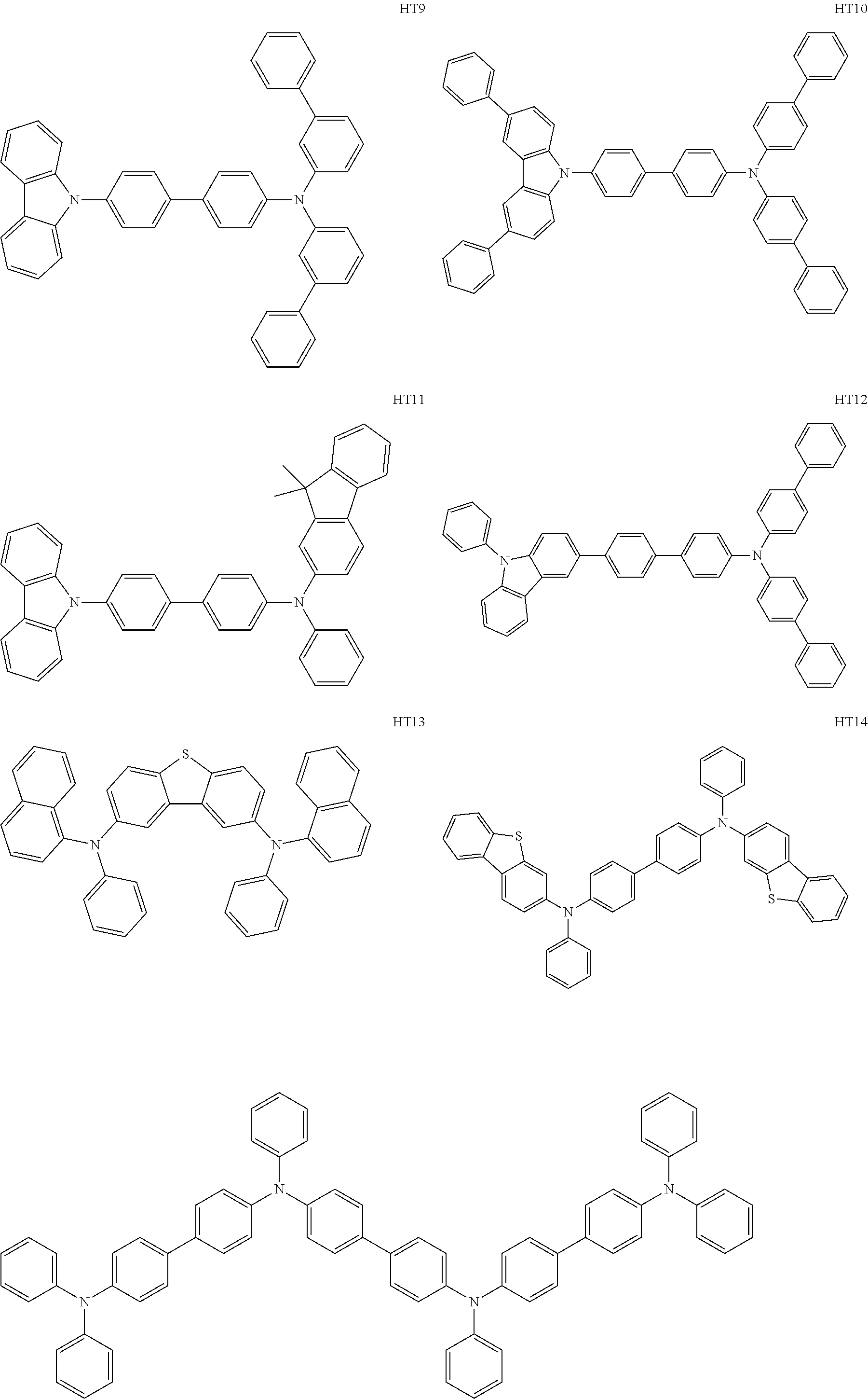

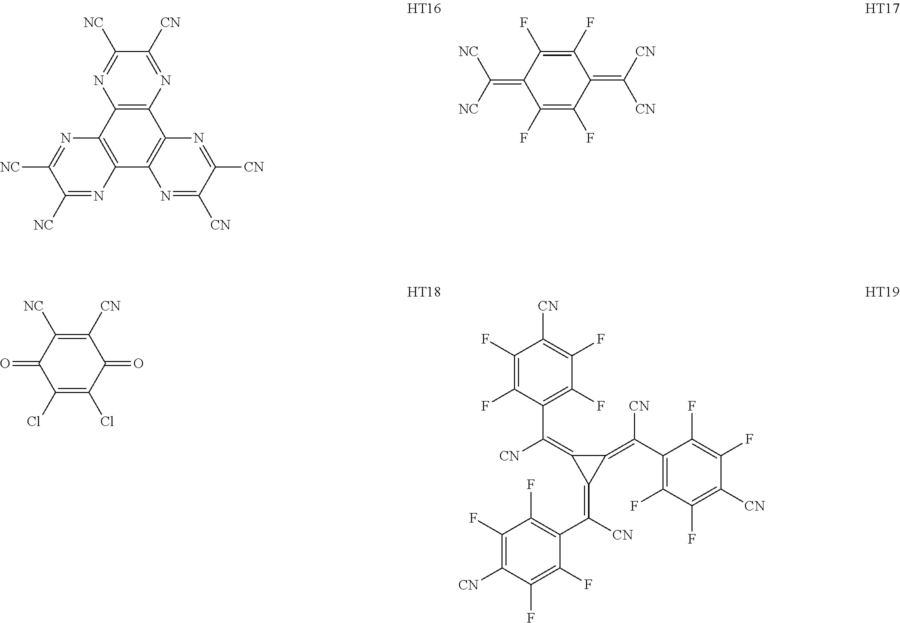

The material used for the hole injection layer may be a compound having a deep LUMO level, such as a hexaazatriphenylene compound, a tetrafluoroquinodimethane compound, or a dichlorodicyanobenzoquinone compound. Specific examples thereof include compounds HT16 to HT19.

The material used for the electron blocking layer may be HT7, HT8, HT9, HT10, HT11, or HT12 having a carbazole group. Such a compound having a carbazole group has a deep HOMO level and enables the formation of a structure in which the HOMO level becomes deeper stepwise in the order of the hole-transporting material, the hole-blocking material, and the light-emitting layers 4a and 4b. Thus, holes can be injected into the light-emitting layers 4a and 4b at a low voltage.

The material used for the electron injection layer may be an alkali metal, an alkaline earth metal, a rare earth metal, or a compound thereof, and generally known materials may be used. Specifically, for example, metallic Ca, LiF, KF, or Cs₂CO₃ is used, and a mixture thereof may be used.

The organic compound layers according to the disclosure may be formed by a dry process such as a vacuum evaporation method, an ionized vapor deposition method, sputtering, or plasma. Alternatively, instead of the dry process, the organic compound layers may be formed by a wet process in which a layer is formed by a publicly known coating method (such as spin coating, dipping, a casting method, a Langmuir-Blodgett (LB) method, or an ink jet method) using a material dissolved in a suitable solvent.

When a layer is formed by, for example, the vacuum evaporation method or the solution coating method, crystallization or the like is unlikely to occur, and the layer has good stability with time. In the case of forming a layer by the coating method, the layer may be formed using a suitable binder resin in combination.

Examples of the binder resin include, but are not limited to, polyvinylcarbazole resins, polycarbonate resins, polyester resins, acrylonitrile-butadiene-styrene (ABS) resins, acrylic resins, polyimide resins, phenolic resins, epoxy resins, silicone resins, and urea resins.

These binder resins may be used alone as a homopolymer or a copolymer or may be used as a mixture of two or more thereof. Furthermore, publicly known additives such as a plasticizer, an oxidation inhibitor, and an ultraviolet absorbent may be optionally used in combination.

### Protective Layer

The organic light-emitting element according to the disclosure may include a protective layer. The protective layer may be a silicon nitride (SiN) layer or a silicon oxynitride (SiON) layer formed by chemical vapor deposition (CVD) or an aluminum oxide layer formed by atomic layer deposition (ALD), or may be formed of a material having very low permeability to oxygen and moisture from the outside, such as silicon oxide or titanium oxide. The protective layer may be formed of a single layer or a plurality of layers as long as the protective layer has a sufficiently high moisture barrier properties. When the protective layer is formed of a plurality of layers, layers individually composed of different materials may be stacked or layers that are composed of the same material but have different densities may be stacked. The protective layer may be formed in consideration of the refractive index so that light emitted from the organic light-emitting element is easily extracted to the outside of the apparatus. The protective layer may also be referred to as a sealing layer. In one embodiment, the thickness of the protective layer is 1.6 μm or more and 3.0 μm or less, and in another embodiment, the thickness of the protective layer is 2.0 μm or more and 2.8 μm or less.

### Planarization Layer

The organic light-emitting element according to the disclosure may include a planarization layer. The planarization layer is a layer for filling irregularities of the protective layer and may be disposed on the protective layer. This structure enables a reduction of scattered light generated at sloped portions of the irregularities on the surface of the protective layer to suppress color mixture. The planarization layer is constituted by, for example, a resin layer formed by coating.

### Color Filter

The organic light-emitting element according to the disclosure may include a color filter. The color filter is formed by applying a color resist onto the planarization layer and patterning the color resist by lithography. The color resist is formed of, for example, a photo-curable resin, and regions irradiated with, for example, ultraviolet rays are cured to form a pattern. The negative/positive form of the pattern obtained by curing with ultraviolet rays may be reversed.

The color filter may have R (red), G (green), and B (blue) color filters. The RGB color filters may be arranged in any of a stripe arrangement, a square arrangement, a delta arrangement, and a Bayer arrangement.

### Filling Layer

The organic light-emitting element according to the disclosure may include a filling layer between the color filter and an opposite substrate described later. The filling layer is formed of, for example, an organic material such as an acrylic resin, an epoxy resin, or a silicone resin. A planarization layer may be formed between the color filter and the filling layer. This planarization layer may be the same as or different from the planarization layer disposed between the color filter and the protective layer. These two planarization layers may be formed of the same material. The use of the same material achieves high adhesion between the planarization layers outside the display region.

### Opposite Substrate

In the embodiments illustrated in FIGS. 1A and 2A, the organic light-emitting element may include an opposite substrate on the opposite side from the substrate 1. The opposite substrate may be, for example, a transparent glass substrate or a transparent plastic substrate.

### Apparatuses Including Organic Light-Emitting Element

The organic light-emitting element according to the disclosure can be used as a constituent member of a display apparatus, an illumination apparatus, or the like. In addition, the organic light-emitting element is applicable to, for example, an exposure light source of an electrophotographic image-forming apparatus, a backlight of a liquid crystal display apparatus, or a light-emitting apparatus including a white light source and a color filter.

The display apparatus may be an image information processing apparatus that includes an image input unit to which image information from an area CCD, a linear CCD, a memory card, or the like is input, includes an information processing unit configured to process input information, and that displays the input image on a display unit. The display apparatus may include a plurality of pixels, and at least one of the plurality of pixels may include the organic light-emitting element according to the disclosure and an active element, such as a transistor, connected to the organic light-emitting element.

A display unit included in an imaging apparatus or an ink jet printer may have a touch panel function. The operation type of this touch panel function is not particularly limited and may be an infrared type, an electrostatic capacitance type, a resistive film type, or an electromagnetic induction type. The display apparatus may be used as a display unit of a multifunctional printer.

Various devices and apparatuses including the organic light-emitting element according to the disclosure will be described below by way of embodiments.

### Image Forming Apparatus

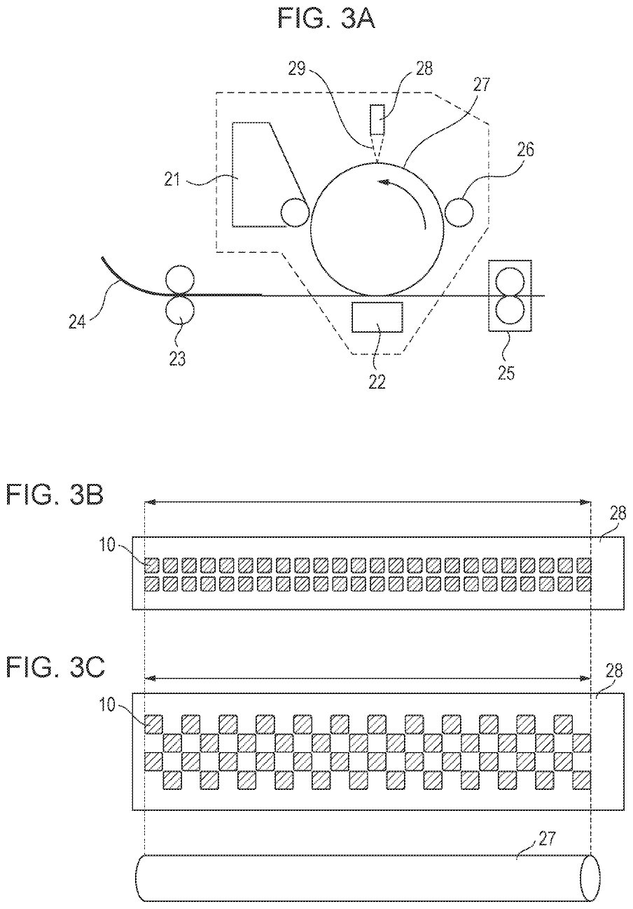

FIG. 3A is a schematic diagram illustrating the configuration of an embodiment of an image forming apparatus including an exposure apparatus according to the disclosure. The image forming apparatus according to this embodiment is an electrophotographic image forming apparatus including a photoreceptor 27, an exposure light source 28, a developing portion 21, a charging portion 26, a transfer unit 22, a transporting portion 23, and a fixing portion 25.

Light 29 is applied from the exposure light source 28, and an electrostatic latent image is formed on the surface of the photoreceptor 27. The exposure light source 28 includes the organic light-emitting element according to the disclosure. The developing portion 21 contains a toner and the like, and the charging portion 26 charges the photoreceptor 27. The transfer unit 22 transfers the developed image to a recording medium 24 such as paper, and the transporting portion 23 transports the recording medium 24. The fixing portion 25 fixes the image formed on the recording medium 24.

FIGS. 3B and 3C are schematic views illustrating the configuration of the exposure light source 28 in which a plurality of organic light-emitting elements 10 according to the disclosure are arranged as light-emitting portions on a long substrate. An arrow in the drawing indicates a direction parallel to the axis of the photoreceptor 27 and a column direction in which the organic light-emitting elements 10 are arranged. This column direction is the same as the direction of the rotational axis of the photoreceptor 27 and may also be referred to as a major-axis direction of the photoreceptor 27.

FIG. 3B illustrates a form in which the organic light-emitting elements 10 are arranged in the major-axis direction of the photoreceptor. FIG. 3C illustrates a form which is different from that in FIG. 3B and in which the organic light-emitting elements 10 are disposed in a staggered manner in a first column and a second column in the column direction. The first column and the second column are arranged at positions different in the row direction. In the first column, a plurality of organic light-emitting elements 10 are arranged at a predetermined spacing. In the second column, organic light-emitting elements 10 are arranged at positions corresponding to the spaces between the organic light-emitting elements 10 of the first column. That is, the plurality of organic light-emitting elements 10 are arranged at a predetermined spacing in the row direction. In other words, the arrangement illustrated in FIG. 3C corresponds to, for example, a state in which the organic light-emitting elements 10 are arranged in a lattice pattern, a state in which the organic light-emitting elements 10 are arranged in a houndstooth check pattern, or a checkered pattern.

### Display Apparatus

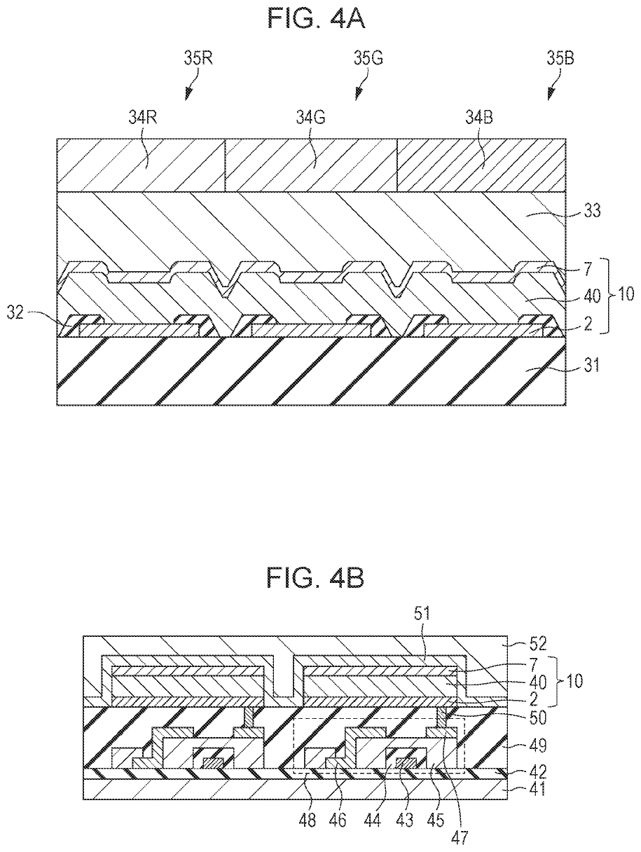

FIGS. 4A and 4B are schematic sectional views of a display apparatus according to an embodiment of the disclosure in the thickness direction. The display apparatus according to the disclosure includes a plurality of pixels, and at least one of the plurality of pixels is the organic light-emitting element according to the disclosure.

FIG. 4A is a schematic sectional view illustrating the configuration of one pixel of a display apparatus including the organic light-emitting elements according to an embodiment of the disclosure. In this embodiment, one pixel has three subpixels 35, and the subpixels 35 are divided into 35R (red light emission), 35G (green light emission), and 35B (blue light emission) in accordance with their light emission. In this embodiment, the organic light-emitting element 10 emits white light, and the white light emitted from the organic light-emitting element 10 is passed through color filters 34R (red), 34G (green), and 34B (blue) to obtain respective emission colors. The subpixels 35R, 35G, and 35B include the organic light-emitting element 10 on an interlayer insulating layer 31 serving as a substrate. In this embodiment, an anode 2 is formed for each subpixel 35, and individual anodes 2 are electrically insulated from each other by respective insulating layers 32.

In this embodiment, since the light is emitted from the side provided with the color filters 34R, 34G, and 34B, a cathode 7 is a transparent electrode, and the anode 2 is a reflective electrode. An organic compound layer 40 and the cathode 7 are common to a plurality of pixels.

In FIG. 4A, a protective layer 33 is provided. The insulating layer 32 is also referred to as a bank or a pixel isolation film, and a region of the anode 2 that is not covered with the insulating layer 32 is in contact with the organic compound layer 40 and serves as a light-emitting region. The protective layer 33 reduces the entry of water into the organic compound layer 40. The protective layer 33 may be formed of a single layer or a plurality of layers. In the case of a plurality of layers, each layer may be an inorganic compound layer or an organic compound layer.

The color filters 34R, 34G, and 34B may be formed on a planarization layer, which is not illustrated in the drawing. Furthermore, a resin protective layer, which is not illustrated in the drawing, may be formed on the color filters 34R, 34G, and 34B. The color filters 34R, 34G, and 34B may be formed on an opposite substrate such as a glass substrate and may then be bonded.

In one embodiment, the size of the light-emitting region surrounded by the insulating layer 32 is 5 μm or more and 15 μm or less. More specifically, the size may be, for example, 11 μm, 9.5 μm, 7.4 μm, or 6.4 μm. The spacing between the subpixels may be 10 μm or less. More specifically, the spacing may be 8 μm, 7.4 μm, or 6.4 μm.

The pixels can have a publicly known arrangement form in plan view. For example, the arrangement form may be the stripe arrangement, the delta arrangement, the PenTile arrangement, or the Bayer arrangement. The subpixels may have any publicly known shape in plan view. For example, the shape may be a quadrangle such as a rectangle or a rhombus, or a hexagon. Of course, the shape is not limited to an accurate figure, and shapes that are close to rectangles are also regarded as rectangles.

The shape of the subpixels and the pixel array may be adopted in combination.

FIG. 4B is a schematic sectional view illustrating the configuration of a pixel of a display apparatus including organic light-emitting elements according to another embodiment of the disclosure. In this embodiment, a transistor 48 is connected to an organic light-emitting element 10. The transistor 48 illustrated in FIG. 4B is a thin-film transistor (TFT) but may be a transistor other than TFT or an active element other than the transistor.

In this embodiment, a substrate 41 made of glass, silicon, or the like and an insulating layer 42 on top of the substrate 41 are provided, and the transistor 48 is arranged on the insulating layer 42. The transistor 48 is composed of a gate electrode 43, a gate insulating film 44, a semiconductor layer 45, a drain electrode 46, and a source electrode 47. An insulating film 49 is disposed on the transistor 48, and an anode 2 of the organic light-emitting element 10 is connected to the source electrode 47 of the transistor 48 through a contact hole 50 formed in the insulating film 49.

The form of electrical connection between the electrodes (anode 2 and cathode 7) included in the organic light-emitting element 10 and the electrodes (source electrode 47 and drain electrode 46) included in the transistor 48 is not limited to the configuration illustrated in FIG. 4B. That is, any configuration may be employed as long as one of the anode 2 and the cathode 7 is electrically connected to one of the source electrode 47 and the drain electrode 46 of the TFT.

In FIG. 4B, protective layers 51 and 52 are provided to suppress deterioration of the organic light-emitting element 10.

The transistors 48 are not limited to TFTs having an active layer (semiconductor layer 45) on the insulating surface of the substrate 41 but may be transistors using a single-crystal silicon wafer. The active layer may be formed of single-crystal silicon, a non-single-crystal silicon such as amorphous silicon or microcrystalline silicon, or a non-single-crystal oxide semiconductor such as indium zinc oxide or indium gallium zinc oxide. Therefore, also in this embodiment, the transistors 48 may be formed inside the substrate 41 such as a silicon substrate. The expression “formed inside the substrate 41” as used herein means that transistors are produced by processing the substrate 41, such as a silicon substrate, itself. In other words, having transistors inside the substrate 41 can also be considered that the substrate 41 and the transistors 48 are integrally formed. Whether the transistors are formed inside the substrate 41 or TFTs are used on the substrate 41 is selected on the basis of the size of the display unit. For example, when the display unit has a size of about 0.5 inches, the organic light-emitting elements can be formed on a silicon substrate.

The emission luminance of the organic light-emitting element 10 according to this embodiment is controlled by the transistors 48 which are one example of switching elements, and thus an image can be displayed at respective emission luminance levels by arranging a plurality of organic light-emitting elements 10 in a plane.

In this embodiment, the organic light-emitting elements 10 may be incorporated in a pixel circuit. The pixel circuit may be an active matrix-type circuit that independently controls light emission of the organic light-emitting elements 10. The active matrix-type circuit may be voltage programming or current programming. A driving circuit has a pixel circuit for each pixel. The pixel circuit may have a transistor that controls the emission luminance of an organic light-emitting element 10, a transistor that controls the timing of light emission, a capacitor that holds the gate voltage of the transistor that controls the emission luminance, and a transistor for connecting to GND without through the organic light-emitting element 10.

The display apparatus has a display region and a peripheral region disposed around the display region. The display region includes a pixel circuit, and the peripheral region includes a display control circuit. The mobility of transistors constituting the pixel circuit may be smaller than the mobility of transistors constituting the display control circuit.

The slope of the current-voltage characteristics of the transistors constituting the pixel circuit may be smaller than the slope of the current-voltage characteristics of the transistors constituting the display control circuit. The slope of the current-voltage characteristics can be measured by the so-called Vg-Ig characteristics.

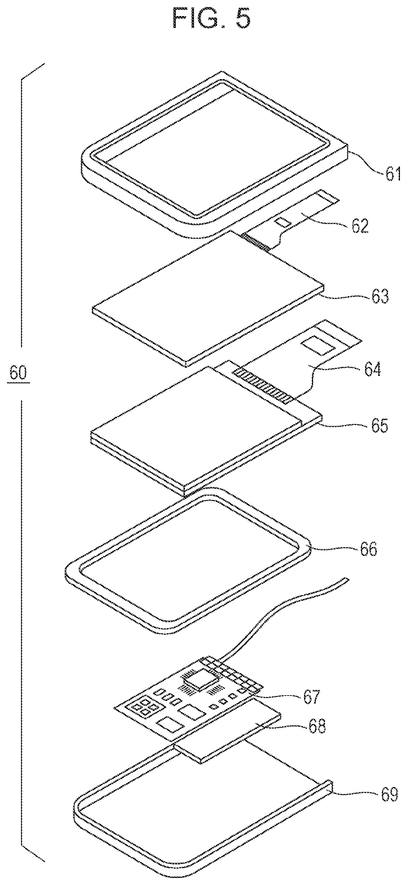

FIG. 5 is an exploded perspective view illustrating the entire configuration of a display apparatus according to an embodiment of the disclosure. A display apparatus 60 includes a touch panel 63, a display panel 65, a frame 66, a circuit substrate 67, and a battery 68 between an upper cover 61 and a lower cover 69. The touch panel 63 and the display panel 65 are connected to flexible printed circuits (FPC) 62 and 64, respectively.

Transistors are printed onto the circuit substrate 67. The battery 68 is not necessarily installed unless the display apparatus is a portable apparatus or may be installed in a different position even when the display apparatus is a portable apparatus.

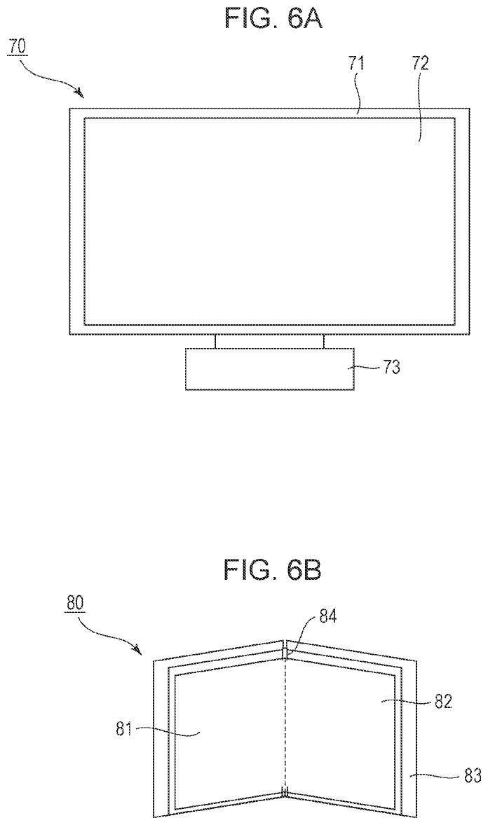

FIGS. 6A and 6B are schematic front views illustrating a display apparatus according to another embodiment of the disclosure. FIG. 6A illustrates a display apparatus such as a television monitor or a PC monitor. A display apparatus 70 includes a frame 71 and a display unit 72. The organic light-emitting element according to the disclosure is used in the display unit 72.

The display apparatus 70 further includes a base 73 that supports the frame 71 and the display unit 72. The base 73 is not limited to the form illustrated in FIG. 6A. The lower side of the frame 71 may also function as the base. In one embodiment, the frame 71 and the display unit 72 may be curved, and the radius of curvature thereof is 5,000 mm or more and 6,000 mm or less.

A display apparatus 80 illustrated in FIG. 6B is a so-called foldable display apparatus configured to be capable of being folded. The display apparatus 80 includes a first display unit 81, a second display unit 82, a housing 83, and an inflexion point 84. The first display unit 81 and the second display unit 82 are formed by using the organic light-emitting element according to the disclosure. The first display unit 81 and the second display unit 82 may be designed as a single, seamless display apparatus. The first display unit 81 and the second display unit 82 can be separated at the inflexion point 84. The first display unit 81 and the second display unit 82 may display images that differ from each other. Alternatively, the first and second display units may collectively display a single image.

### Imaging Apparatus

The organic light-emitting element according to the disclosure is used in a display unit of an imaging apparatus including an optical unit that includes a plurality of lenses and an imaging element that receives light that has passed through the optical unit. The imaging apparatus includes a display unit that displays information acquired by the imaging element. The display unit may be a display unit exposed to the outside of the imaging apparatus or a display unit disposed in a viewfinder. Examples of the imaging apparatus include digital cameras and digital camcorders.

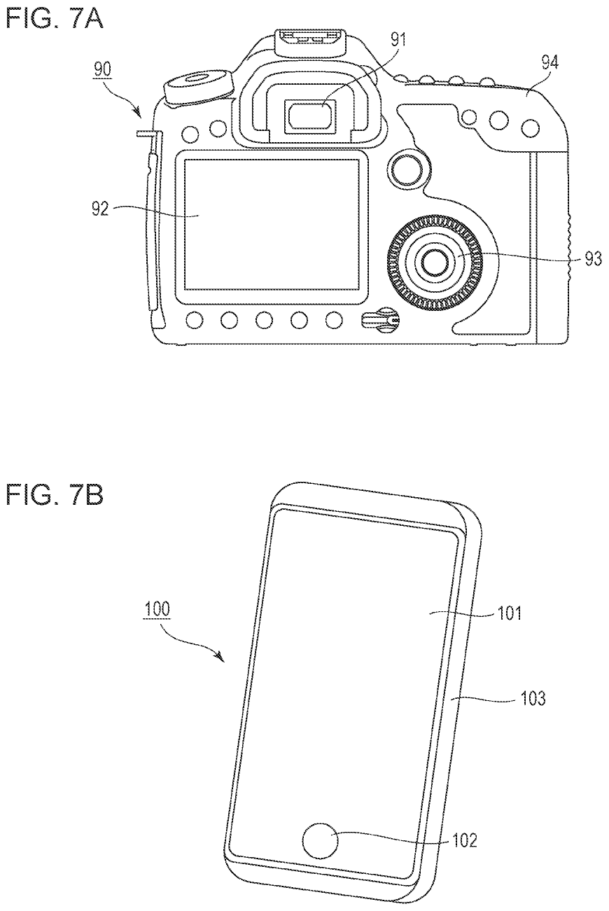

FIG. 7A is a schematic front view illustrating an imaging apparatus according to an embodiment of the disclosure. An imaging apparatus 90 of this embodiment includes a viewfinder 91, a rear surface display 92, an operation unit 93, and a housing 94, and the viewfinder 91 is the display unit including the organic light-emitting element according to the disclosure. The viewfinder 91 may display not only an image to be captured but also, for example, environmental information and imaging instructions. The environmental information may include, for example, the intensity of external light, the direction of external light, the moving speed of the subject, and the possibility that the subject may hide behind an obstacle.

Since the suitable timing for capturing an image is a very short period of time, information is displayed as quickly as possible. Since organic light-emitting elements have a high response speed, the use of the organic light-emitting element according to the disclosure realizes quick display. Thus, the display unit including the organic light-emitting element is suitably used compared with a liquid crystal display apparatus when a high display speed is desired.

The imaging apparatus 90 includes an optical unit, which is not illustrated in the drawing. The optical unit includes a plurality of lenses and is configured to form an image on an imaging element housed in the housing 94. The focal point can be adjusted by adjusting the relative positions of the plurality of lenses. This operation may also be automatically performed. The imaging apparatus may be referred to as a photoelectric conversion apparatus. The image capturing method of the photoelectric conversion apparatus may include, instead of a method of successively capturing images, a method of detecting a difference from the previous image and a method of extracting images from continuously recorded images.

### Electronic Device

The organic light-emitting element according to the disclosure may be used in a display unit of a portable terminal. In such a case, both a display function and an operation function may be provided. Examples of the portable terminal include mobile phones such as smart phones, tablets, and head mount displays.

FIG. 7B is a schematic perspective view of an electronic device according to an embodiment of the disclosure. An electronic device 100 includes a display unit 101, an operation unit 102, and a housing 103. The housing 103 includes therein circuits, a printed circuit board having the circuits, a battery, and a communication unit. The operation unit 102 may be a button or a touch panel-type responsive unit. The operation unit 102 may be a biometric authentication unit configured to, for example, recognize the fingerprints and release the lock. The electronic device that includes a communication unit may also be referred to as a communication device. The electronic device may include a lens and an imaging element so as to further have a camera function. An image captured by the camera function is displayed on the display unit. Examples of the electronic device include smart phones and notebook computers.

### Illumination Apparatus

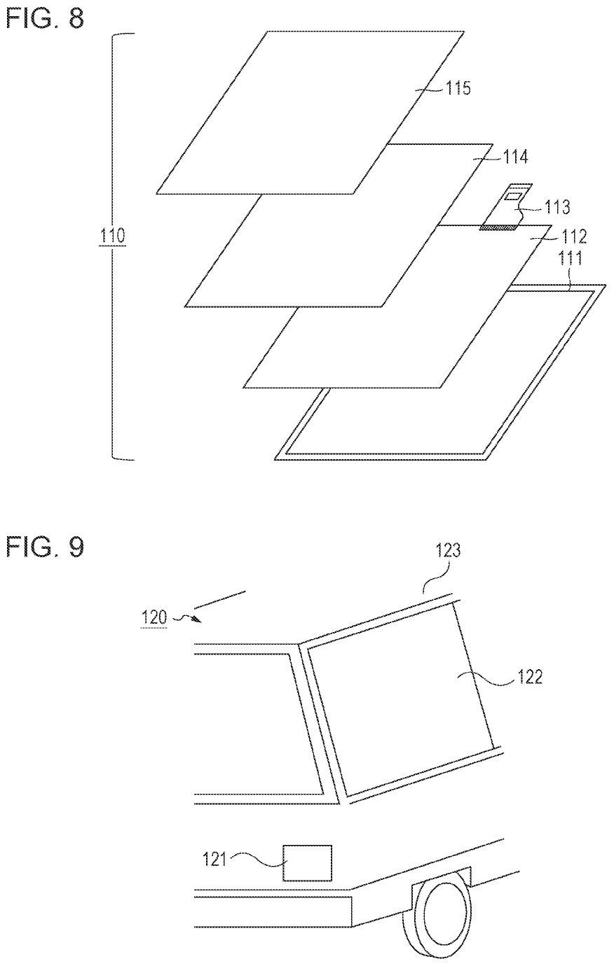

FIG. 8 is an exploded perspective view illustrating an illumination apparatus according to an embodiment of the disclosure. An illumination apparatus 110 of this embodiment includes a housing 111, a light source 112, a circuit substrate 113, and an optical filter 114 and a light diffusion unit 115 that transmit light emitted from the light source 112. The light source 112 is formed by using the organic light-emitting element according to the disclosure and a power supply circuit connected to the organic light-emitting element. The power supply circuit is a circuit configured to convert alternating-current voltage to direct-current voltage. The optical filter 114 may be a filter that improves the color rendering properties of the light source 112. The light diffusion unit 115 can effectively diffuse light emitted from the light source 112 and allow the light to reach a wide range, for example, for lighting up. The optical filter 114 and the light diffusion unit 115 are disposed on the light-output side of the illumination. A cover may be optionally disposed on the outermost portion.

The illumination apparatus 110 is, for example, an apparatus that illuminates the inside of a room. The illumination apparatus 110 may emit light of any color of white, neutral white, and colors from blue to red. The illumination apparatus 110 may include a light modulating circuit configured to modulate the light. The white is a color having a color temperature of 4,200 K, and the neutral white is a color having a color temperature of 5,000 K. The illumination apparatus 110 may include a color filter.

The illumination apparatus 110 may include a heat dissipation unit. The heat dissipation unit dissipates heat in the apparatus to the outside of the apparatus. The heat dissipation unit may be formed of, for example, a metal having a high specific heat or liquid silicone.

### Moving Object

The moving object according to the disclosure may be, for example, a ship, an aircraft, or a drone. The moving object includes a body and a lighting fixture disposed on the body. The lighting fixture includes the organic light-emitting element according to the disclosure and serves to emit light to indicate the position of the body.

FIG. 9 is a schematic perspective view illustrating an automobile which is an embodiment of the moving object according to the disclosure. An automobile 120 of this embodiment includes a tail lamp 121 serving as a lighting fixture, and the tail lamp 121 lights up when, for example, the brakes are applied. The automobile 120 includes a car body 123 and a window 122 attached to the car body 123. In this embodiment, at least one of the tail lamp 121 and the window 122 includes the organic light-emitting element according to the disclosure.

The tail lamp 121 may include a protective member that protects the organic light-emitting element.

The protective member may be composed of any material that has relatively high strength and is transparent, and may be composed of a polycarbonate or the like. The polycarbonate may be mixed with a furandicarboxylic acid derivative, an acrylonitrile derivative, or the like.

The window 122 may be a transparent display unless it is a window for checking the front and rear of the automobile. When the transparent display includes the organic light-emitting element according to the disclosure, constituent members, such as the electrodes, of the organic light-emitting element are provided as transparent members.

### Imaging Display Apparatus

An imaging display apparatus including the organic light-emitting element according to the disclosure is applicable to systems that can be worn as wearable devices, such as glasses (smart glasses), head mount displays (HMDs), and smart contact lenses. The imaging display apparatus used in such application examples includes an imaging apparatus capable of photoelectrically converting visible light and a display apparatus capable of emitting visible light.

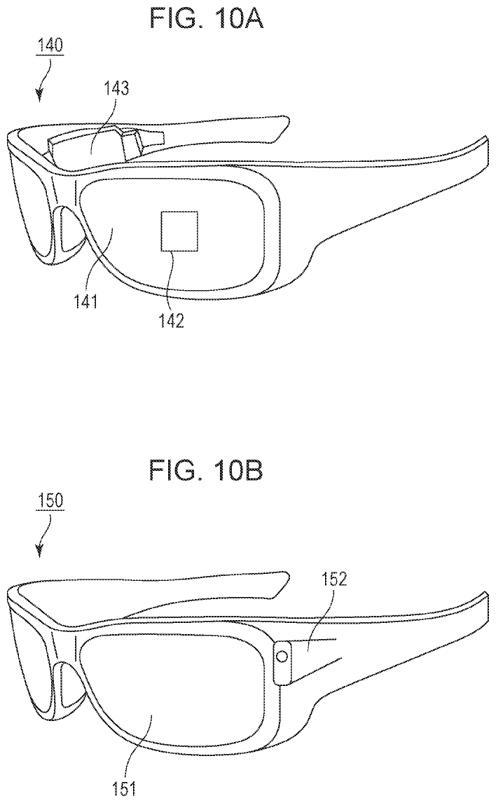

FIG. 10A illustrates glasses 140 which are one of application examples of the imaging display apparatus. An imaging apparatus 142 such as a complementary metal-oxide semiconductor (CMOS) sensor or a single-photon avalanche diode (SPAD) is disposed on the front surface side of a lens 141 of the glasses 140. A display apparatus (not illustrated) including the organic light-emitting element according to the disclosure is disposed on the back surface side of the lens 141.

The glasses 140 further include a control apparatus 143. The control apparatus 143 functions as a power supply that supplies electric power to the imaging apparatus 142 and the display apparatus according to each embodiment. The control apparatus 143 controls the operations of the imaging apparatus 142 and the display apparatus. An optical system for focusing light on the imaging apparatus 142 is formed on the lens 141.

FIG. 10B also illustrates glasses, but the configuration of the glasses is slightly different from that in FIG. 10A. Glasses 150 in FIG. 10B include a control apparatus 152. An imaging apparatus corresponding to the imaging apparatus 142 in FIG. 10A and a display apparatus including the organic light-emitting element according to the disclosure are mounted on the control apparatus 152. A lens 151 includes an optical system for projecting light emitted from the display apparatus and the imaging apparatus in the control apparatus 152, and an image is projected on the lens 151. The control apparatus 152 functions as a power supply that supplies electric power to the imaging apparatus and the display apparatus and controls the operations of the imaging apparatus and the display apparatus. The control apparatus 152 may include a gaze detection unit that detects the gaze of the wearer. Infrared radiation may be used to detect the gaze. An infrared light-emitting unit emits infrared light to an eyeball of the user who is gazing at a displayed image. An image of the eyeball is captured by detecting the infrared light reflected from the eyeball with an imaging unit including light-receiving elements. The deterioration of the image quality is reduced by providing a reducing unit that reduces light from the infrared light-emitting unit to a display unit in plan view.

The gaze of the user to the displayed image is detected from the image of the eyeball captured with the infrared light. Any publicly known method is applicable to the gaze detection using the captured image of the eyeball. As one example, a gaze detection method based on a Purkinje image formed by the reflection of irradiation light at the cornea may be employed.

More specifically, a gaze detection process based on a pupil-corneal reflection method is performed. By using the pupil-corneal reflection method, the gaze of the user is detected by calculating a gaze vector representing the direction (rotation angle) of the eyeball on the basis of the image of the pupil and the Purkinje image included in the captured image of the eyeball.

The imaging display apparatus of this embodiment may include an imaging apparatus including light-receiving elements and may control an image displayed on the display apparatus on the basis of the gaze information of the user from the imaging apparatus. Specifically, the display apparatus determines a first field-of-view region at which the user gazes and a second field-of-view region other than the first field-of-view region on the basis of the gaze information. The first field-of-view region and the second field-of-view region may be determined by the control apparatus of the display apparatus or may be determined by receiving those determined by an external control apparatus. In the display region of the display apparatus, the display resolution of the first field-of-view region may be controlled to be higher than the display resolution of the second field-of-view region. That is, the resolution of the second field-of-view region may be made lower than that of the first field-of-view region.

The display region includes a first display region and a second display region different from the first display region. A region having a high priority is determined from the first display region and the second display region on the basis of the gaze information. The first display region and the second display region may be determined by the control apparatus of the display apparatus or may be determined by receiving those determined by an external control apparatus. The resolution of the high priority region may be controlled to be higher than the resolution of a region other than the high priority region. That is, the resolution of the region having a relatively low priority may be lowered.

Artificial intelligence (AI) may be used to determine the first field-of-view region and the region having a high priority. The AI may be a model configured to estimate the angle of the gaze and the distance to a target object located in the gaze direction on the basis of the image of the eyeball, using, as training data, the image of the eyeball and the actual direction of gaze of the eyeball in the image. The AI program may be stored in the display apparatus, the imaging apparatus, or an external apparatus. When the AI program is stored in the external apparatus, the AI program is transmitted to the display apparatus through communication.

In the case of controlling the display on the basis of visual recognition detection, an application is suitably made to smart glasses further including an imaging apparatus that captures an external image. The smart glasses can display the captured external information in real time.

### EXAMPLES

### Example 1

### Evaluations of HOMO and LUMO Levels

Host materials, light-emitting dopant materials, functional layer materials, and electron transport layer materials were evaluated by the methods described below. Tables 1 and 2 show measured values of the HOMO level and the LUMO level.

### Method for Evaluating HOMO Level

A thin film having a thickness of 30 nm was formed on an aluminum substrate, and the HOMO level of the thin film was measured with an AC-3 (manufactured by Riken Keiki Co., Ltd.).

### Method for Evaluating LUMO Level

A thin film having a thickness of 30 nm was formed on a quartz substrate. The optical band gap (absorption edge) of the measurement material was determined using the thin film with a spectrophotometer (V-560 manufactured by JASCO Corporation). The sum obtained by adding the above HOMO level value to the optical band gap value was determined as the LUMO level.

The second decimal place of the values shown below may include a measurement error. Accordingly, in the disclosure, the second decimal place was rounded off, and the rounded values were used as numerical values of the energy levels serving as standards for material selection when elements of Examples and Comparative Examples were produced.

TABLE 1

| | | Measured value | |
|---|---|---|---|
| | | HOMO | LUMO |
| | Compound | [eV] | [eV] |
| Host | EM1 | −6.02 | −3.10 |
| | EM2 | −5.96 | −3.04 |
| | EM3 | −5.94 | −2.95 |
| | EM4 | −6.09 | −3.06 |
| | EM5 | −6.03 | −3.06 |
| | EM7 | −6.01 | −3.13 |
| | EM10 | −6.31 | −2.83 |
| | EM13 | −5.99 | −3.06 |
| | EM17 | −5.73 | −3.53 |
| | EM22 | −5.80 | −3.20 |
| | EM27 | −6.22 | −3.11 |
| Blue dopant | BD1 | −5.46 | −2.67 |
| | BD4 | −5.56 | −2.77 |
| | BD8 | −6.05 | −3.26 |
| | BD9 | −6.08 | −3.38 |
| | BD15 | −6.10 | −3.40 |
| | BD19 | −6.11 | −3.48 |
| | BD20 | −5.90 | −3.30 |
| | BD23 | −6.20 | −3.52 |
| | BD24 | −6.08 | −3.38 |
| | BD25 | −6.10 | −3.40 |

TABLE 2

| | | Measured value | |
|---|---|---|---|
| | | HOMO | LUMO |
| | Compound | [eV] | [eV] |
| Red dopant | RD2 | −5.40 | −3.30 |
| | RD5 | −5.61 | −3.63 |
| | RD10 | −5.60 | −3.55 |
| | RD15 | −5.55 | −3.50 |
| | RD21 | −5.62 | −3.59 |
| Green dopant | GD3 | −5.40 | −2.60 |
| | GD4 | −5.58 | −3.03 |
| | GD7 | −5.77 | −3.57 |
| | GD9 | −5.94 | −3.45 |
| | GD10 | −5.87 | −3.49 |
| | GD11 | −5.82 | −3.51 |
| | GD22 | −5.90 | −3.40 |
| | GD27 | −5.84 | −3.52 |
| Functional | FL4 | −6.04 | −3.00 |
| layer | FL6 | −6.02 | −3.10 |
| | FL7 | −5.96 | −3.04 |
| | FL8 | −5.94 | −2.95 |
| | FL9 | −6.00 | −3.01 |
| | FL14 | −6.03 | −3.06 |
| | FL16 | −6.01 | −3.13 |
| | FL18 | −5.73 | −3.53 |
| | FL23 | −5.80 | −3.20 |
| Electron | ET2 | −6.12 | −3.07 |
| transport layer | ET7 | −6.23 | −2.99 |
| | ET13 | −6.08 | −3.17 |

### Example 2

In this Example, a blue organic light-emitting element having a top emission structure was produced in which an anode, a hole injection layer, a hole transport layer, an electron blocking layer, a first light-emitting layer, a functional layer, an electron transport layer, an electron injection layer, and a cathode were sequentially formed on a substrate.

On a glass substrate, Al (65 nm)/Ti (6 nm) were deposited by a sputtering method, and the resulting multilayer film was patterned by photolithography to form an anode. At this time, the area of the electrode facing a cathode was adjusted to 3 mm².

Subsequently, the substrate having the electrode after being cleaned, and materials were attached to a vacuum vapor deposition apparatus (manufactured by ULVAC, Inc.). The apparatus was evacuated to 1.0×10⁻⁴ Pa (1×10⁻⁶ Torr), and UV/ozone cleaning was then conducted. Subsequently, layers were formed so as to have the layer configuration shown in Table 3 below.

The resulting blue organic light-emitting element has configuration <1> and configurations <5> and <6> of the disclosure. In addition, formulae [4] and [3-1] in configuration <1> are satisfied.

TABLE 3

| | | | | Thickness |
|---|---|---|---|---|
| | Material | | | [nm] |
| Hole injection layer | HT16 | | | 7 |
| Hole transport layer | HT2 | | | 18 |
| Electron blocking layer | HT7 | | | 10 |
| First light-emitting layer | Host | EM1 | Mass ratio | 13 |
| (Blue-light-emitting layer) | Blue dopant | BD24 | EM1:BD24 = 98.8:1.2 | |

| Functional layer | FL8 | | 70 |
|---|---|---|---|
| Electron transport layer | ET2 | | 30 |
| Electron injection layer | LiF | | 0.8 |
| Cathode | Mg | Mass ratio | 12 |
| | Ag | Mg:Ag = 50:50 | |

After the formation of the cathode, the substrate was moved into a glove box and sealed, in a nitrogen atmosphere, with a glass cap containing a drying agent. Thus, a blue organic light-emitting element was obtained.

The blue organic light-emitting element obtained as described above was connected to a voltage application device, and characteristics of the organic light-emitting element were evaluated. Current-voltage characteristics were measured with a microammeter 4140B manufactured by Hewlett-Packard Company. The acquisition of an emission spectrum and the evaluation of chromaticity were performed with a spectroradiometer “SR-3” manufactured by Topcon Corporation. The emission luminance was measured with a luminance colorimeter BM7 manufactured by Topcon Corporation.

The efficiency, the voltage, and the CIE chromaticity coordinates during display at 1,000 cd/m² were 3.3 cd/A, 3.4 V, and (0.16, 0.18), respectively. Thus, the resulting element was a good blue organic light-emitting element having a high efficiency and a low drive voltage.

Next, a direct current of 120 mA was continuously applied, and a change in emission luminance with time was measured with BM7 manufactured by Topcon Corporation. According to the results, the time taken for the luminance to be decreased by 5% was 90 hours. Thus, the resulting element was a blue organic light-emitting element having good durability.

### Example 3

An element was produced and evaluated as in Example 2 except that the materials used in the light-emitting layer and the functional layer were changed to the materials shown in Table 4.

According to the results, the efficiency, the voltage, and the CIE chromaticity coordinates during display at 1,000 cd/m² were 3.2 cd/A, 3.4 V, and (0.16, 0.17), respectively. Thus, the resulting element was a good blue organic light-emitting element as in Example 2.

The time taken for the luminance to be decreased by 5% was 100 hours. Thus, the resulting element was a blue organic light-emitting element having good durability.

### Comparative Example 1

An element was produced and evaluated as in Example 2 except that the materials used in the light-emitting layer and the functional layer were changed to the materials shown in Table 4. This element does not satisfy the relation of formula [3] in configuration <1> of the disclosure.

The efficiency, the voltage, and the CIE chromaticity coordinates of the element during display at 1,000 cd/m² were 3.5 cd/A, 3.7 V, and (0.16, 0.17), respectively. The resulting element was a blue organic light-emitting element having a higher light emitting efficiency than Example 2.

However, the time taken for the luminance to be decreased by 5% was 40 hours. Thus, the resulting element was a blue organic light-emitting element having poor durability compared with the element of Example 2.

TABLE 4

| | | | First light-emitting layer | | | | | |
|---|---|---|---|---|---|---|---|---|
| | Host (First host) | | Blue dopant (First dopant) | | Functional layer | | Electron transport layer | |
| | HOMO [eV] | LUMO [eV] | HOMO [eV] | LUMO [eV] | HOMO [eV] | LUMO [eV] | HOMO [eV] | LUMO [eV] |
| Example 2 | EM1 | | BD24 | | FL8 | | ET2 | |
| | −6.02 | −3.10 | −6.08 | −3.38 | −5.94 | −2.95 | −6.12 | −3.07 |
| Example 3 | EM4 | | BD23 | | FL4 | | ET2 | |
| | −6.09 | −3.06 | −6.20 | −3.52 | −6.04 | −3.00 | −6.12 | −3.07 |
| Comparative | EM1 | | BD24 | | EM4 | | ET2 | |
| Example 1 | −6.02 | −3.10 | −6.08 | −3.38 | −6.09 | −3.06 | −6.12 | −3.07 |

### Example 4

In this Example, a white organic light-emitting element having a top emission structure was produced in which an anode, a hole injection layer, a hole transport layer, an electron blocking layer, a first light-emitting layer, a second light-emitting layer, a functional layer, an electron transport layer, an electron injection layer, and a cathode were sequentially formed on a substrate. The element was produced and evaluated as in Example 2 except that the second light-emitting layer was deposited. The layer configuration is shown in Table 5.

The resulting white organic light-emitting element has configuration <1> and configurations <2> to <6> of the disclosure. Furthermore, formulae [4] and [3-1] in configuration <1> and formulae [5-1] in configuration <2> are also satisfied.

TABLE 5

| | | | | Thick- |
|---|---|---|---|---|
| | | | | ness |
| | Material | | | [nm] |
| Hole injection layer | HT16 | | | 7 |
| Hole transport layer | HT2 | | | 18 |
| Electron blocking layer | HT7 | | | 10 |
| Second light-emitting | Second | EM1 | Mass ratio | 7 |
| layer) | host | | EM1:RD5:GD10 = | |
| (Red- and green-light- | Red | RD5 | 97.6:0.4:2.0 | |
| emitting layer | dopant | | | |
| | Green | GD10 | | |
| | dopant | | | |
| First light-emitting layer | First host | EM1 | Mass ratio | 13 |
| (Blue-light-emitting | Blue | BD24 | EM1:BD24 = | |
| layer) | dopant | | 99.4:0.6 | |
| Functional layer | FL8 | | | 70 |
| Electron transport layer | ET2 | | | 30 |
| Electron injection layer | LIF | | | 0.8 |
| Cathode | Mg | | Mass ratio | 12 |
| | Ag | | Mg:Ag = 50:50 | |

The efficiency, the voltage, and the CIE chromaticity coordinates during display at 1,000 cd/m² were 7.1 cd/A, 3.5 V, and (0.25, 0.30), respectively. Thus, the resulting element was a good white organic light-emitting element having a high efficiency and a low drive voltage.

The time taken for the luminance to be decreased by 5% was 1,100 hours. Thus, the resulting element was a white organic light-emitting element having good durability.

### Examples 5 to 12

Elements were produced and evaluated as in Example 4 except that the materials used in the light-emitting layers and the functional layer were changed to the materials shown in Table 6.

According to the results of the evaluations, the efficiency, the voltage, and the CIE chromaticity coordinates of the organic light-emitting elements of Examples 5 to 12 were substantially the same as those characteristics of the element of Example 4. Thus, the elements were good white organic light-emitting elements having a low drive voltage and good durability.

The time taken for the luminance to be decreased by 5% was as follows.

### Example 5: 1,200 h

### Example 6: 1,100 h

### Example 7: 1,200 h

### Example 8: 1,000 h

### Example 9: 1,100 h

### Example 10: 1,000 h

### Example 11: 1,200 h

### Example 12: 1,100 h

The white organic light-emitting elements produced here have configuration <1> of the disclosure and further have configurations <2> to <6> of the disclosure as in Example 4. Furthermore, formulae [4] and [3-1] or [3-2] in configuration <1> are satisfied, and formula [5-1] in configuration <2> is satisfied. Accordingly, white organic light-emitting elements having a high efficiency, a low drive voltage, and good durability were considered to be produced as in Example 4.

### Comparative Example 2

An element was produced as in Example 4 except that EM4 was used as the material of the functional layer as shown in Table 6. This element does not satisfy the relation of formula [3] in configuration <1> of the disclosure.

Accordingly, the efficiency, the voltage, and the CIE chromaticity coordinates during display at 1,000 cd/m² were 7.0 cd/A, 3.8 V, and (0.22, 0.21), respectively. The chromaticity of the resulting element was close to blue compared with that of Example 4. Thus, the resulting element was an element having a high blue emission luminance but having a high voltage.

The time taken for the luminance to be decreased by 5% was 800 hours. Thus, the resulting element was a white organic light-emitting element having poor durability compared with the element of Example 4.

### Comparative Example 3

An element was produced as in Example 5 except that ET7 was used as the material of the functional layer as shown in Table 6. This element does not satisfy the relation of formula [3] in configuration <1> of the disclosure. In addition, the element does not have configurations <5> and <6> of the disclosure.

Accordingly, the efficiency, the voltage, and the CIE chromaticity coordinates during display at 1,000 cd/m² were 7.1 cd/A, 4 V, and (0.24, 0.28), respectively. The resulting element was an element having a high voltage.

The time taken for the luminance to be decreased by 5% was 650 hours. Thus, the resulting element was a white organic light-emitting element having poor durability compared with the element of Example 5.

TABLE 6

| | Host | | First light- | | | | | | | | | |
|---|---|---|---|---|---|---|---|---|---|---|---|---|
| | (Common to first | | emitting layer | | Second Light-emitting layer | | | | | | | |
| | host and second | | Blue dopant | | Red dopant | | Green dopant | | Functional | | Electron | |
| | host) | | (First dopant) | | (Second dopant) | | (Third dopant) | | layer | | transport layer | |
| | HOMO | LUMO | HOMO | LUMO | HOMO | LUMO | HOMO | LUMO | HOMO | LUMO | HOMO | LUMO |
| | [eV] | [eV] | [eV] | [eV] | [eV] | [eV] | [eV] | [eV] | [eV] | [ eV] | [eV] | [eV] |
| Example 4 | EM1 | | BD24 | | RD5 | | GD10 | | FL8 | | ET2 | |
| | −6.02 | −3.10 | −6.08 | −3.38 | −5.61 | −3.63 | −5.87 | −3.49 | −5.94 | −2.95 | −6.12 | −3.07 |
| Example 5 | EM4 | | BD23 | | RD5 | | GD9 | | FL4 | | ET2 | |
| | −6.09 | −3.06 | −6.20 | −3.52 | −5.61 | −3.63 | −5.94 | −3.45 | −6.04 | −3.00 | −6.12 | −3.07 |
| Example 6 | EM5 | | BD23 | | RD21 | | GD10 | | FL8 | | ET2 | |
| | −6.03 | −3.06 | −6.20 | −3.52 | −5.62 | −3.59 | −5.87 | −3.49 | −5.94 | −2.95 | −6.12 | −3.07 |
| Example 7 | EM4 | | BD23 | | RD5 | | GD11 | | FL8 | | ET2 | |
| | −6.09 | −3.06 | −6.20 | −3.52 | −5.61 | −3.63 | −5.82 | −3.51 | −5.94 | −2.95 | −6.12 | −3.07 |
| Example 8 | EM1 | | BD23 | | RD5 | | GD9 | | FL8 | | ET2 | |
| | −6.02 | −3.10 | −6.20 | −3.52 | −5.61 | −3.63 | −5.94 | −3.45 | −5.94 | −2.95 | −6.12 | −3.07 |
| Example 9 | EM4 | | BD23 | | RD5 | | GD9 | | FL8 | | ET2 | |
| | −6.09 | −3.06 | −6.20 | −3.52 | −5.61 | −3.63 | −5.94 | −3.45 | −5.94 | −2.95 | −6.12 | −3.07 |
| Example 10 | EM1 | | BD24 | | RD5 | | GD9 | | FL4 | | ET2 | |
| | −6.02 | −3.10 | −6.08 | −3.38 | −5.61 | −3.63 | −5.94 | −3.45 | −6.04 | −3.00 | −6.12 | −3.07 |
| Example 11 | EM4 | | BD23 | | RD21 | | GD9 | | FL4 | | ET2 | |
| | −6.09 | −3.06 | −6.20 | −3.52 | −5.62 | −3.59 | −5.94 | −3.45 | −6.04 | −3.00 | −6.12 | −3.07 |
| Example 12 | EM4 | | BD23 | | RD5 | | GD10 | | FL4 | | ET2 | |
| | −6.09 | −3.06 | −6.20 | −3.52 | −5.61 | −3.63 | −5.87 | −3.49 | −6.04 | −3.00 | −6.12 | −3.07 |
| Comparative | EM1 | | BD24 | | RD5 | | GD10 | | EM4 | | ET2 | |
| Example 2 | −6.02 | −3.10 | −6.08 | −3.38 | −5.61 | −3.63 | −5.87 | −3.49 | −6.09 | −3.06 | −6.12 | −3.07 |
| Comparative | EM4 | | BD23 | | RD5 | | GD9 | | ET7 | | ET2 | |
| Example 3 | −6.09 | −3.06 | −6.20 | −3.52 | −5.61 | −3.63 | −5.94 | −3.45 | −6.23 | −2.99 | −6.12 | −3.07 |

As described above, according to the disclosure, an organic light-emitting element which has a low voltage and whose durability is unlikely to decrease and devices and apparatuses including the element are provided by providing a light-emitting layer and a functional layer whose energy levels satisfy specific relations.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-016846 filed Feb. 7, 2022, which is hereby incorporated by reference herein in its entirety.

What is claimed is:

1. An organic light-emitting element comprising, in sequence:
an anode;
a first light-emitting layer;
a functional layer in contact with the first light-emitting layer; and
a cathode,
wherein the first light-emitting layer contains a first host material and a first dopant material, and
when the first host material has a LUMO energy level LUMOₕ₁, the first dopant material has a LUMO energy level LUMO_{d1}, the first host material has a HOMO energy level HOMOₕ₁, the first dopant material has a HOMO energy level HOMO_{d1}, and an organic material that forms the functional layer has a HOMO energy level HOMO_{FL}, formulae [1] to [3] are satisfied:
LUMOₕ₁>LUMO_{d1} [1]
HOMOₕ₁>HOMO_{d1} [2]
HOMO_{FL}>HOMOₕ₁ [3].

2. The organic light-emitting element according to claim 1, wherein formula [4] is satisfied:

|LUMOₕ₁−LUMO_{d1}|>|HOMOₕ₁−HOMO_{d1}| [4].

3. The organic light-emitting element according to claim 1, wherein formula [3-1] is satisfied:
HOMO_{FL}−HOMOₕ₁≥0.05 [eV] [3-1].

4. The organic light-emitting element according to claim 1, wherein formula [3-2] is satisfied:
HOMO_{FL}−HOMOₕ₁≥0.15 [eV] [3-2].

5. The organic light-emitting element according to claim 1, further comprising:
a second light-emitting layer on an anode side of the first light-emitting layer while being in contact with the first light-emitting layer,
wherein the second light-emitting layer contains a second host material and a second dopant material, and
when the second dopant material has a HOMO energy level HOMO_{d2} and the second host material has a HOMO energy level HOMOₕ₂, formula [5] is satisfied:
HOMO_{d2}>HOMOₕ₂ [5].

6. The organic light-emitting element according to claim 5, wherein formula [5-1] is satisfied:
HOMO_{d2}−HOMOₕ₂>0.4 [eV] [5-1].

7. The organic light-emitting element according to claim 5, wherein the first host material and the second host material are the same.

8. The organic light-emitting element according to claim 5,
wherein the second light-emitting layer contains a third dopant material,
the first dopant material is a blue light-emitting dopant material,
the second dopant material is a red light-emitting dopant material,
the third dopant material is a green light-emitting dopant material, and
when the third dopant material has a HOMO energy level HOMO_{d3}, formula [6] is satisfied:
HOMO_{d3}>HOMOₕ₂ [6].

9. The organic light-emitting element according to claim 1, wherein the organic material that forms the functional layer is composed of a hydrocarbon alone.

10. The organic light-emitting element according to claim 1, further comprising:
an electron transport layer formed of an organic material and disposed on a cathode side of the functional layer while being in contact with the functional layer,
wherein when the organic material that forms the functional layer has a HOMO energy level HOMO_{FL} and the organic material that forms the electron transport layer has a HOMO energy level HOMO_{ETL}, formula [7] is satisfied:
HOMO_{FL}>HOMO_{ETL} [7].

11. A display apparatus comprising:
a plurality of pixels,
wherein at least one of the pixels includes the organic light-emitting element according to claim 1 and an active element connected to the organic element.

12. An imaging apparatus comprising:
an optical unit that includes a plurality of lenses;
an imaging element that receives light that has passed through the optical unit; and
a display unit,
wherein the display unit displays information acquired by the imaging element and includes the display apparatus according to claim 11.

13. An electronic device comprising:
a housing;
a communication unit that communicates with an external unit; and
a display unit,
wherein the display unit includes the display apparatus according to claim 11.

14. An illumination apparatus comprising:
a light source; and
a light diffusion unit or an optical filter,
wherein the light source includes the organic light-emitting element according to claim 1.

15. A moving object comprising:
a body; and
a lighting fixture disposed on the body,
wherein the lighting fixture includes the organic light-emitting element according to claim 1.

16. An exposure light source of an electrophotographic image-forming apparatus, the exposure light source comprising the organic light-emitting element according to claim 1.

17. The exposure light source according to claim 16, wherein inequality [4] is satisfied:

|LUMOₕ₁−LUMO_{d1}|>|HOMOₕ₁−HOMO_{d1}| [4].

18. The exposure light source according to claim 16, wherein formula [3-1] is satisfied:
HOMO_{FL}−HOMOₕ₁≥0.05 [eV] [3-1].

19. The exposure light source according to claim 16, wherein formula [3-2] is satisfied:
HOMO_{FL}−HOMOₕ₁≥0.15 [eV] [3-2].

20. The exposure light source according to claim 16, wherein the organic light-emitting element further comprising:
a second layer on an anode side of the first layer while being in contact with the first layer,
wherein the second layer contains a second host material and a second dopant material, and
when the second dopant material has a HOMO energy level HOMO_{d2} and the second host material has a HOMO energy level HOMOₕ₂, formula [5] is satisfied:
HOMO_{d2}>HOMOₕ₂ [5].
